(19) United States
(12) Patent Application Publication
(10) Pub. No.: US 2024/0421070 A1
(43) Pub. Date: Dec. 19, 2024

(54) SEMICONDUCTOR DEVICES AND METHODS OF FABRICATING THE SAME

(71) Applicant: SAMSUNG ELECTRONICS CO., LTD., Suwon-si (KR)

(72) Inventors: Sunjung LEE, Suwon-si (KR); Sanghoon AHN, Suwon-si (KR); Donggon YOO, Suwon-si (KR); Jangeun LEE, Suwon-si (KR); Jeongwon HWANG, Suwon-si (KR)

(21) Appl. No.: 18/409,491

(22) Filed: Jan. 10, 2024

(30) Foreign Application Priority Data
Jun. 19, 2023 (KR) 10-2023-0078202

(51) Int. Cl. H01L 23/522; H01L 21/768; H01L 23/532; H01L 29/06; H01L 29/423; H01L 29/775; H01L 29/786

(52) U.S. Cl. CPC H01L 23/5226; H01L 21/76802; H01L 21/76843; H01L 21/76877; H01L 23/53266; H01L 29/0673; H01L 29/42392; H01L 29/775; H01L 29/78696; H01L 29/41775

(57) ABSTRACT

Disclosed are semiconductor devices and their fabrication methods. The semiconductor device comprises a substrate including an active pattern; a channel pattern on the active pattern; a source/drain pattern electrically connected to the channel pattern; a gate electrode on the channel pattern; an interlayer dielectric layer on the gate electrode, wherein the interlayer dielectric layer includes a recess; a via in the recess; a wiring line on the interlayer dielectric layer and electrically connected to the via; and an adhesion layer between the wiring line and an upper surface of the interlayer dielectric layer, wherein an upper surface of the via is closer than the upper surface of the interlayer dielectric layer to the substrate in a first direction, wherein the first direction is perpendicular to an upper surface of the substrate and wherein a portion of the adhesion layer is on a portion of an inner sidewall of the recess.

### CROSS-REFERENCE TO RELATED APPLICATION

This U.S. nonprovisional application claims priority under 35 U.S.C. § 119 to Korean Patent Application No. 10-2023-0078202 filed on Jun. 19, 2023 in the Korean Intellectual Property Office, the disclosure of which is hereby incorporated by reference in its entirety.

### BACKGROUND

The present inventive concepts relate to semiconductor devices, and more particularly, to semiconductor devices including a field effect transistor.

Semiconductor devices may include an integrated circuit including metal oxide semiconductor field effect transistors (MOSFETs). As sizes and design rules of the semiconductor devices are gradually decreased, sizes of the MOSFETs are also increasingly scaled down. The scale down of MOSFETs may deteriorate operating characteristics of the semiconductor devices. Accordingly, various studies have been conducted to develop methods of fabricating semiconductor devices having superior performances while overcoming limitations caused by high integration of the semiconductor devices.

### SUMMARY

Some embodiments of the present inventive concepts provide semiconductor devices with improved electrical properties and increased reliability.

Some embodiments of the present inventive concepts provide methods of fabricating semiconductor devices with improved electrical properties and increased reliability.

The object of the present inventive concepts is not limited to the mentioned above, and other objects which have not been mentioned above will be clearly understood to those skilled in the art from the following description.

According to some embodiments of the present inventive concepts, a semiconductor device may comprise: a substrate that includes an active pattern; a channel pattern on the active pattern; a source/drain pattern electrically connected to the channel pattern; a gate electrode on the channel pattern; an interlayer dielectric layer on the gate electrode, wherein the interlayer dielectric layer includes a recess; a via in the recess of the interlayer dielectric layer; a wiring line on the interlayer dielectric layer and electrically connected to the via; and an adhesion layer between the wiring line and an upper surface of the interlayer dielectric layer, wherein an upper surface of the via is closer than the upper surface of the interlayer dielectric layer to the substrate in a first direction, wherein the first direction is perpendicular to an upper surface of the substrate and wherein a portion of the adhesion layer is on a portion of an inner sidewall of the recess.

According to some embodiments of the present inventive concepts, a semiconductor device may comprise: a substrate that includes an active pattern; a device isolation layer adjacent to the active pattern; a channel pattern on the active pattern, wherein the channel pattern includes a plurality of semiconductor patterns that are stacked and spaced apart from each other in a first direction, and wherein the first direction is perpendicular to an upper surface of the substrate; a source/drain pattern electrically connected to the plurality of semiconductor patterns; a gate electrode that extends around the plurality of semiconductor patterns; an active contact electrically connected to the source/drain pattern; a gate contact electrically connected to the gate electrode; an interlayer dielectric layer on the active contact and the gate contact, wherein the interlayer dielectric layer includes a recess; a via in the recess of the interlayer dielectric layer and electrically connected to the active contact or the gate contact; a plurality of wiring lines on the interlayer dielectric layer; and an adhesion layer between the interlayer dielectric layer and the plurality of wiring lines, wherein one of the plurality of wiring lines is electrically connected to the via, and wherein the adhesion layer extends from an upper surface of the interlayer dielectric layer to a portion of an inner sidewall of the recess.

According to some embodiments of the present inventive concepts, a method of fabricating a semiconductor device may comprise: forming an interlayer dielectric layer on a substrate; patterning the interlayer dielectric layer to form a recess; forming a via in the recess; forming an adhesion layer that is on a portion of an inner sidewall of the recess and an upper surface of the interlayer dielectric layer, wherein the adhesion layer exposes an upper surface of the via; forming a wiring layer on the adhesion layer and the upper surface of the via; and patterning the wiring layer to form a plurality of wiring lines, wherein the upper surface of the via is lower than the upper surface of the interlayer dielectric layer with respect to an upper surface of the substrate in a first direction, and wherein the first direction is perpendicular to the upper surface of the substrate.

### BRIEF DESCRIPTION OF DRAWINGS

FIGS. 1 to 3 illustrate conceptual views showing logic cells of a semiconductor device according to some embodiments of the present inventive concepts.

FIG. 4 illustrates a plan view showing a semiconductor device according to some embodiments of the present inventive concepts.

FIGS. 5A, 5B, 5C, and 5D illustrate cross-sectional views taken along lines A-A′, B-B′, C-C′, and D-D′ of FIG. 4, respectively, showing a semiconductor device according to some embodiments of the present inventive concepts.

FIGS. 6A to 6E illustrate enlarged views of section E depicted in FIG. 5C, showing a semiconductor device according to some embodiments of the present inventive concepts.

FIGS. 7A to 15D illustrate cross-sectional views showing a method of fabricating a semiconductor device according to some embodiments of the present inventive concepts.

FIGS. 7A, 8A, 9A, 10A, 11A, 12A, 13A, 14A, and 15A illustrate cross-sectional views taken along line A-A′ of FIG. 4.

FIGS. 8B, 9B, 10B, 11B, 12B, 13B, 14B, and 15B illustrate cross-sectional views taken along line B-B′ of FIG. 4.

FIGS. 8C, 9C, 10C, 11C, 12C, 13C, 14C, and 15C illustrate cross-sectional views taken along line C-C′ of FIG. 4.

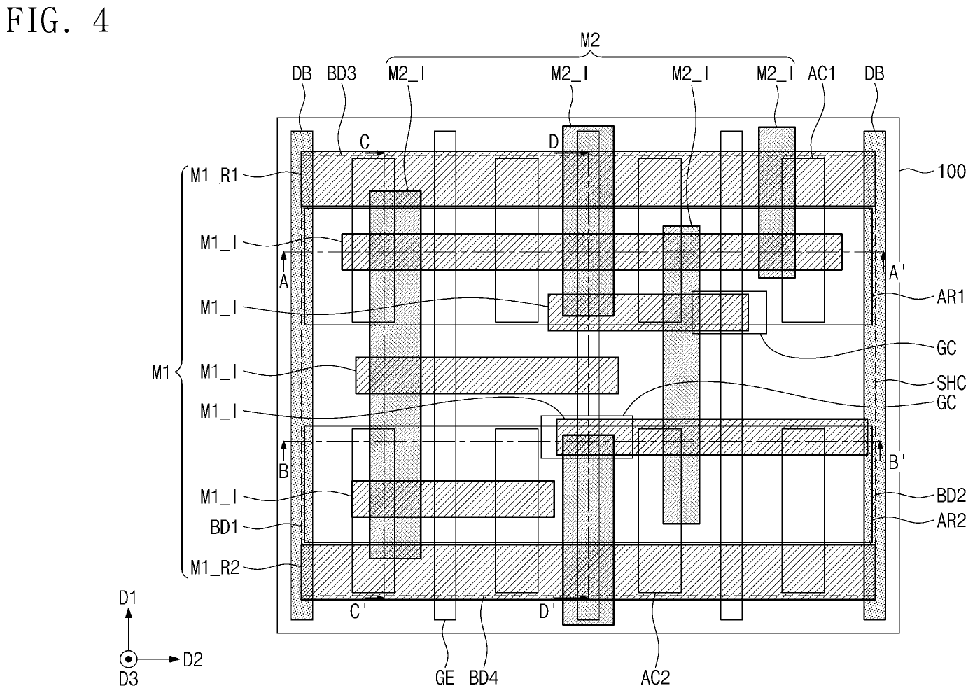

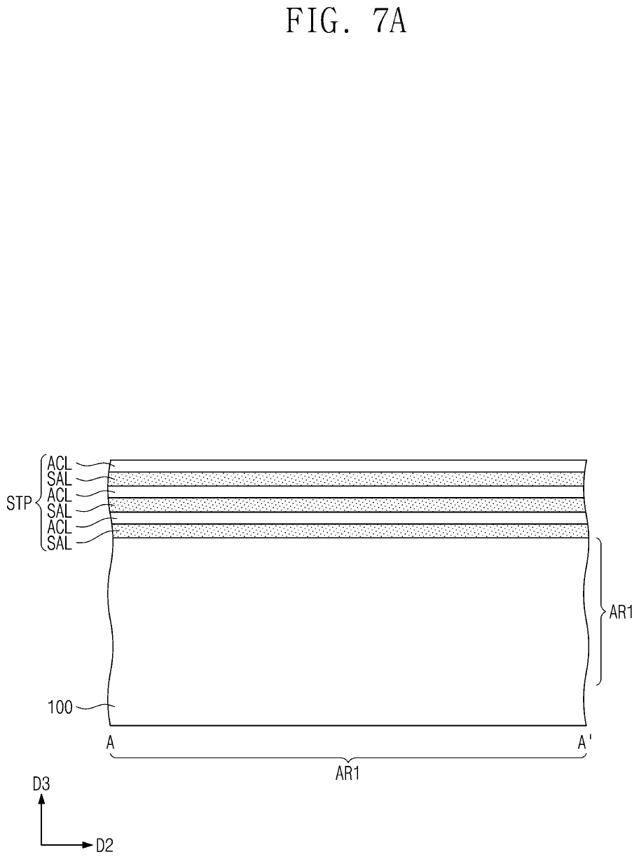

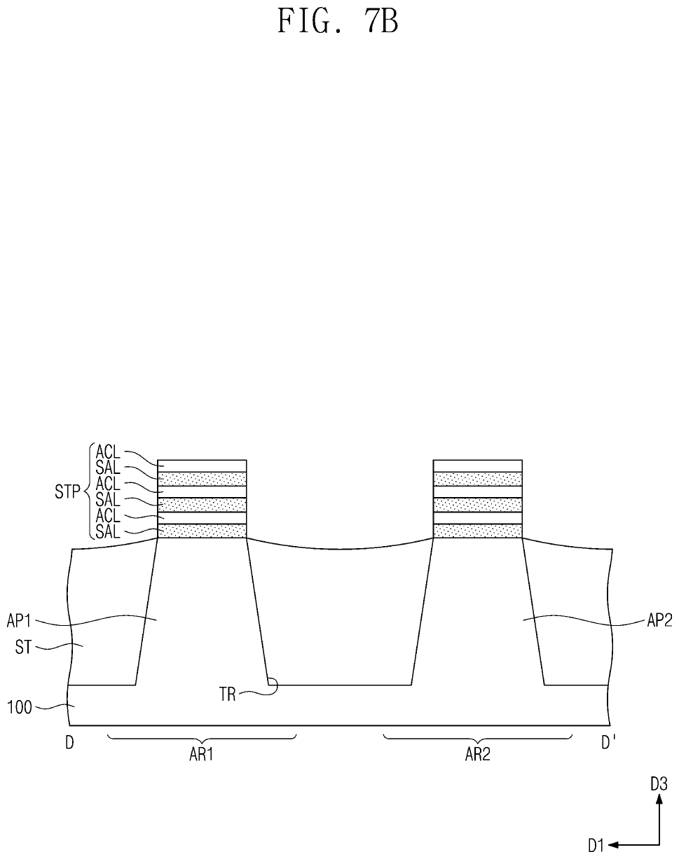

FIGS. 7B, 9D, 10D, 11D, 12D, 13D, 14D, and 15D illustrate cross-sectional views taken along line D-D′ of FIG. 4.

FIGS. 16A to 18D illustrate cross-sectional views showing a method of fabricating a semiconductor device according to some embodiments of the present inventive concepts.

FIGS. 16A, 17A, and 18A illustrate cross-sectional views taken along line A-A′ of FIG. 4.

FIGS. 16B, 17B, and 18B illustrate cross-sectional views taken along line B-B′ of FIG. 4.

FIGS. 16C, 17C, and 18C illustrate cross-sectional views taken along line C-C′ of FIG. 4.

FIGS. 16D, 17D, and 18D illustrate cross-sectional views taken along line D-D′ of FIG. 4.

### DETAILED DESCRIPTION OF EMBODIMENTS

The following will now describe some embodiments of the present inventive concepts with reference to the accompanying drawings. Like reference numerals may indicate like components throughout the description unless clearly stated otherwise.

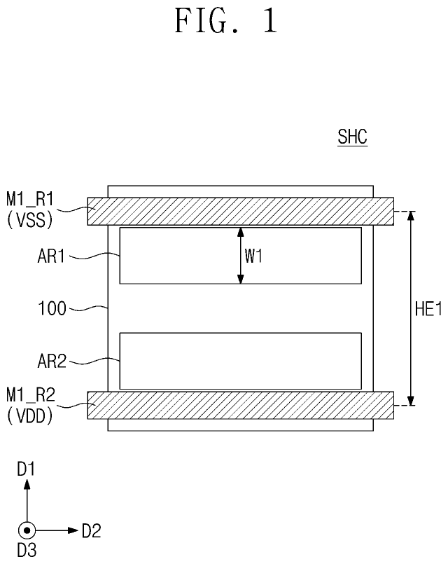

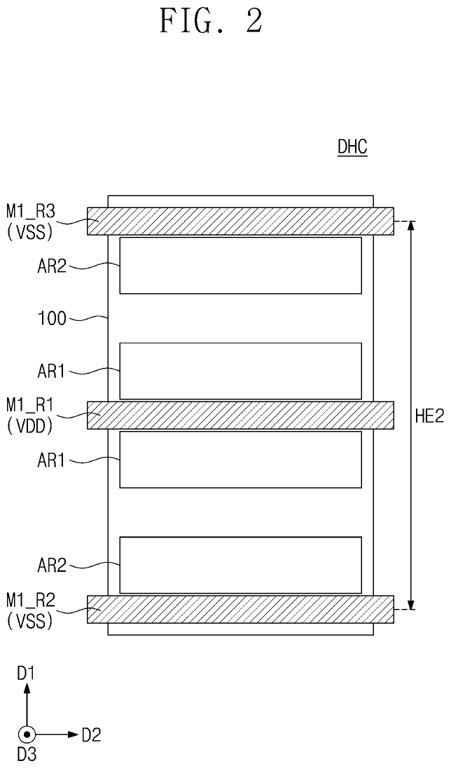

FIGS. 1 to 3 illustrate conceptual views showing logic cells of a semiconductor device according to some embodiments of the present inventive concepts.

Referring to FIG. 1, a single height cell SHC may be provided. For example, a substrate 100 may be provided thereon with a first power line M1_R1 and a second power line M1_R2. For example, the first power line M1_R1 may be a path to which a source voltage VSS is provided, and the second power line M1_R2 may be a path to which a drain voltage VDD is provided.

The single height cell SHC may be defined between the first power line M1_R1 and the second power line M1_R2. The single height cell SHC may include one first active region AR1 and one second active region AR2. One of the first and second active regions AR1 and AR2 may be a PMOSFET region, and the other of the first and second active regions AR1 and AR2 may be an NMOSFET region. The single height cell SHC may have a complementary metal oxide semiconductor (CMOS) structure provided between the first power line M1_R1 and the second power line M1_R2.

Each of the first and second active regions AR1 and AR2 may have a first width W1 in a first direction D1. A first height HE1 may be defined to indicate a length in the first direction D1 of the single height cell SHC. The first height HE1 may be substantially the same as a distance (e.g., pitch) between the first power line M1_R1 and the second power line M1_R2. The first direction D1 may extend in parallel with an upper surface of the substrate 100.

The single height cell SHC may constitute one logic cell. In this description, the logic cell may mean a logic device, such as AND, OR, XOR, XNOR, and inverter, that performs a specific function. For example, the logic cell may include transistors for constituting a logic device, and may also include wiring lines that connect (e.g., electrically connect) the transistors to each other. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection.

Referring to FIG. 2, a double height cell DHC may be provided. For example, a substrate 100 may be provided thereon with a first power line M1_R1, a second power line M1_R2, and a third power line M1_R3. The first power line M1_R1 may be disposed between the second power line M1_R2 and the third power line M1_R3. For example, the second and third power lines M1_R2 and M1_R3 may be a path to which a source voltage VSS is provided, and the first power line M1_R1 may be a path to which a drain voltage VDD is provided.

The double height cell DHC may be defined between the second power line M1_R2 and the third power line M1_R3. The double height cell DHC may include two first active regions AR1 and two second active regions AR2.

One of the two second active regions AR2 may be adjacent to the second power line M1_R2. The other of the two second active regions AR2 may be adjacent to the third power line M1_R3. The two first active regions AR1 may be adjacent to the first power line M1_R1. When viewed in plan, the first power line M1_R1 may be disposed between the two first active regions AR1.

A second height HE2 may be defined to indicate a length in the first direction D1 of the double height cell DHC. The second height HE2 may be about twice the first height HE1 of FIG. 1. The two first active regions AR1 of the double height cell DHC may be collectively connected (e.g., electrically connected) to act as one active region.

In the present inventive concepts, the double height cell DHC shown in FIG. 2 may be defined as a multi-height cell. Although not shown, the multi-height cell may include a triple height cell whose cell height is about three times that of the single height cell SHC in FIG. 1.

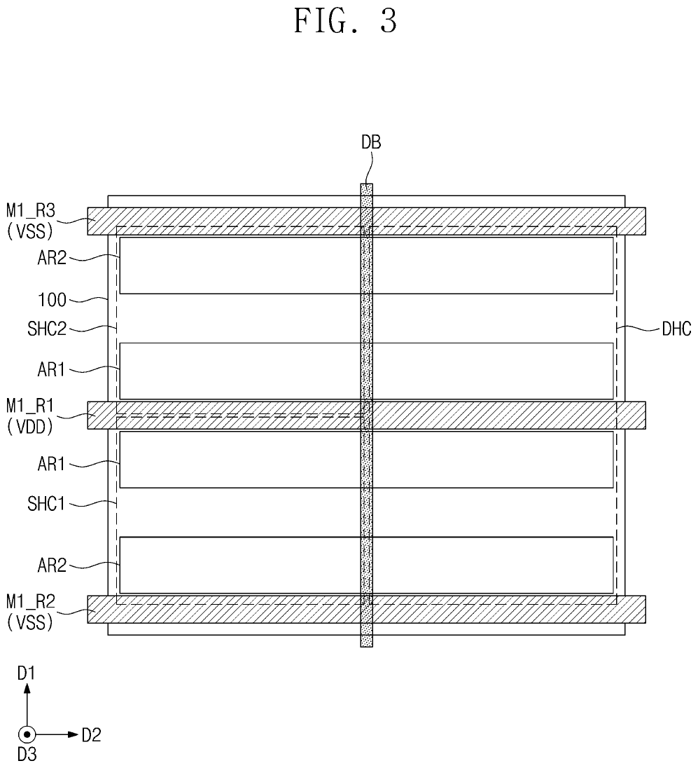

Referring to FIG. 3, a substrate 100 may be provided thereon with a first single height cell SHC1, a second single height cell SHC2, and a double height cell DHC that are two-dimensionally disposed. The first single height cell SHC1 may be disposed between a first power line M1_R1 and a second power line M1_R2. The second single height cell SHC2 may be disposed between the first power line M1_R1 and a third power line M1_R3. The second single height cell SHC2 may be adjacent in the first direction DI to the first single height cell SHC1.

The double height cell DHC may be disposed between the second power line M1_R2 and the third power line M1_R3. The double height cell DHC may be adjacent in a second direction D2 to the first and second single height cells SHC1 and SHC2. The second direction D2 may extend parallel with the upper surface of the substrate 100. The first direction D1 and the second direction D2 may intersect (e.g., may be perpendicular) to each other.

A separation structure DB may be provided between the first single height cell SHC1 and the double height cell DHC and between the second single height cell SHC2 and the double height cell DHC. The separation structure DB may electrically separate an active region (e.g., the first active region AR1 and/or the second active region AR2) of the double height cell DHC from an active region (e.g., the first active region AR1 and/or the second active region AR2) of each of the first and second single height cells SHC1 and SHC2.

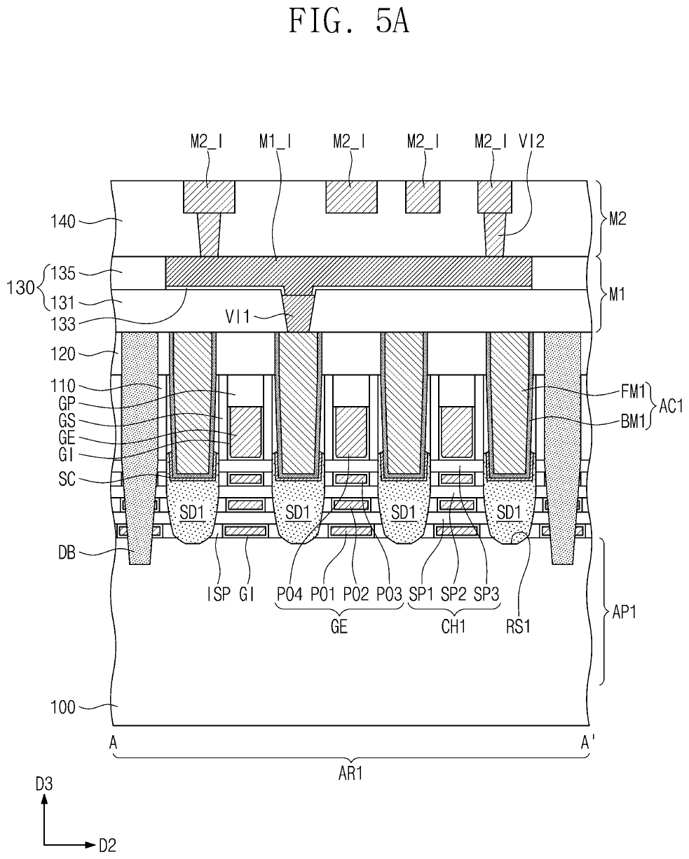

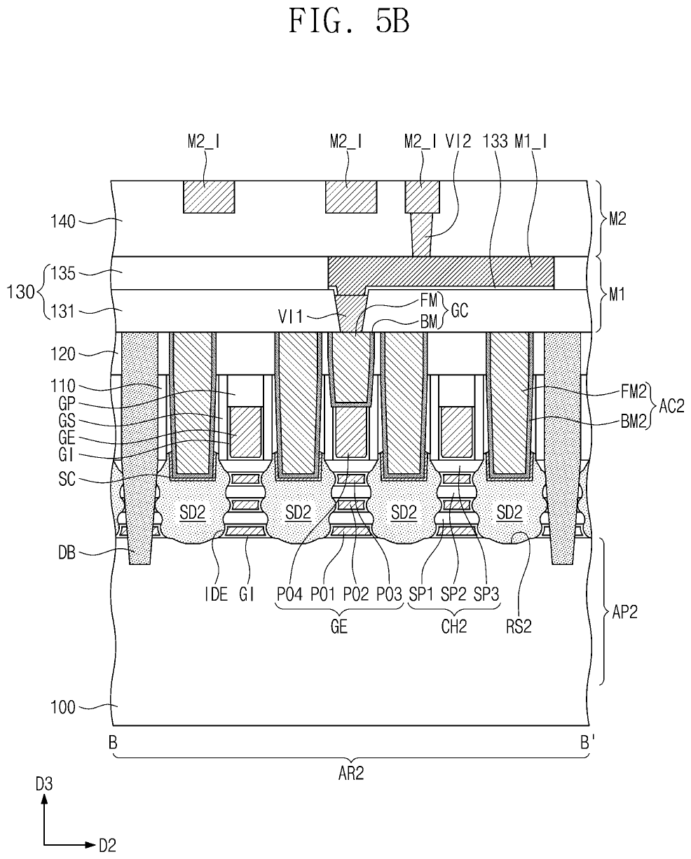

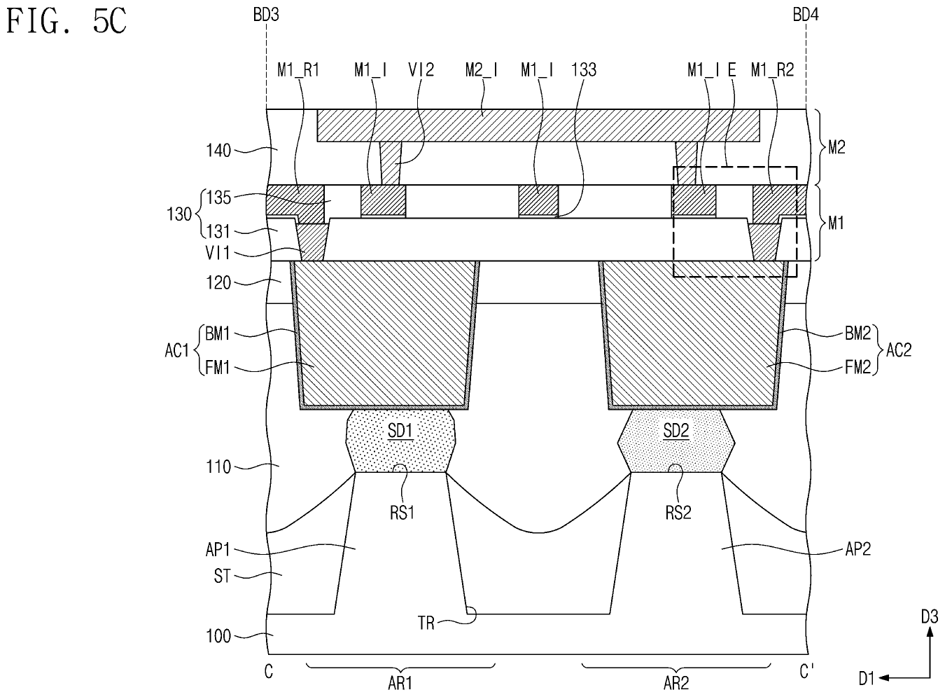

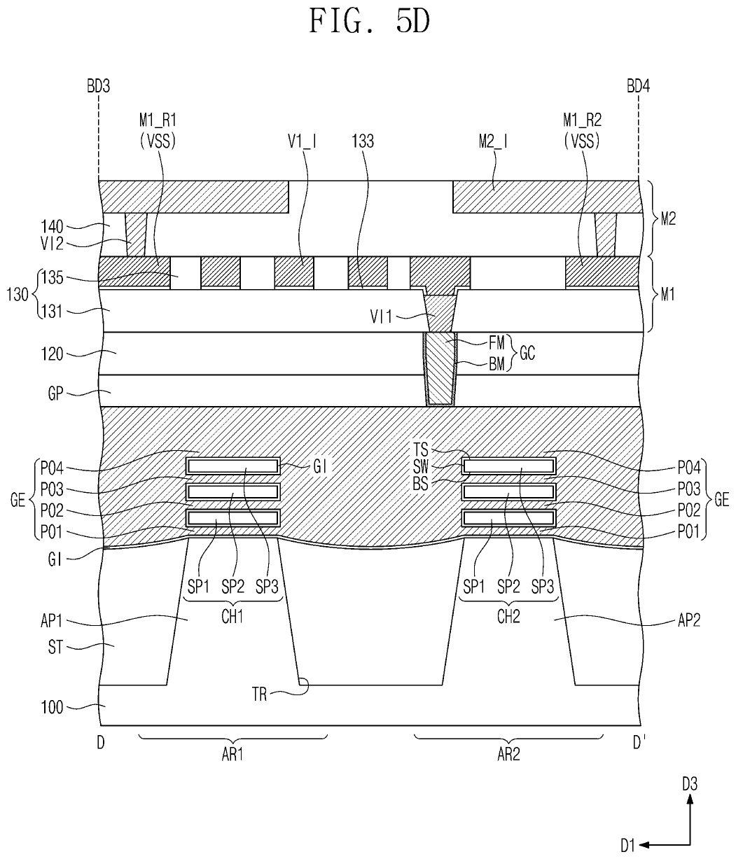

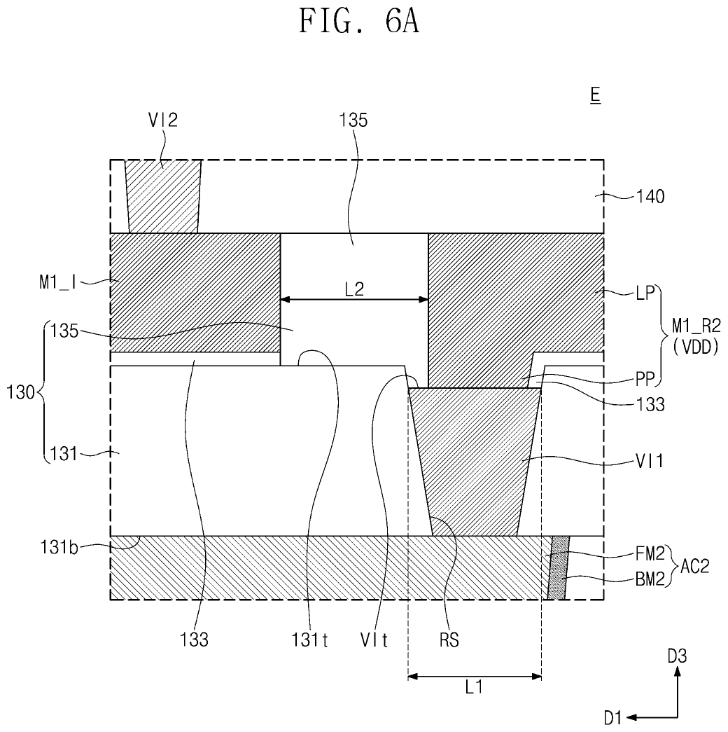

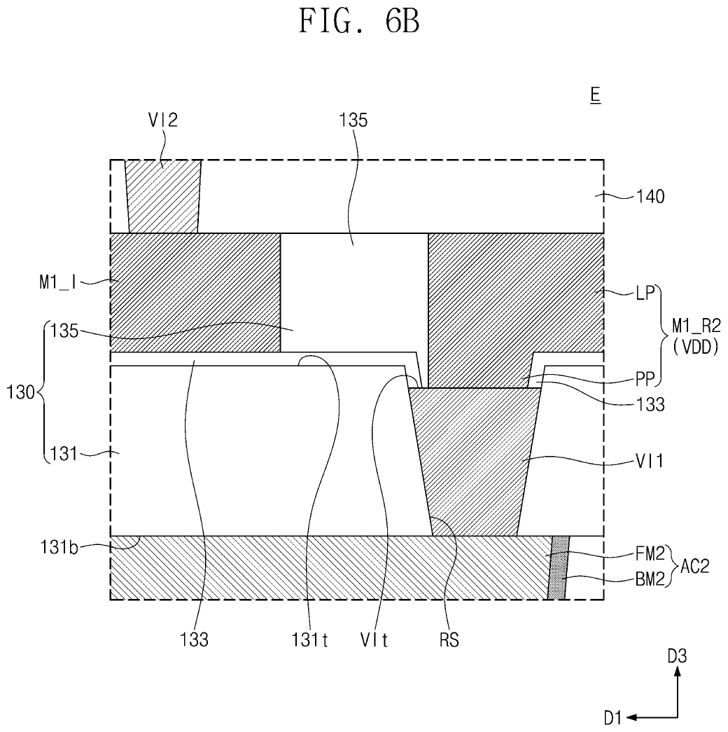

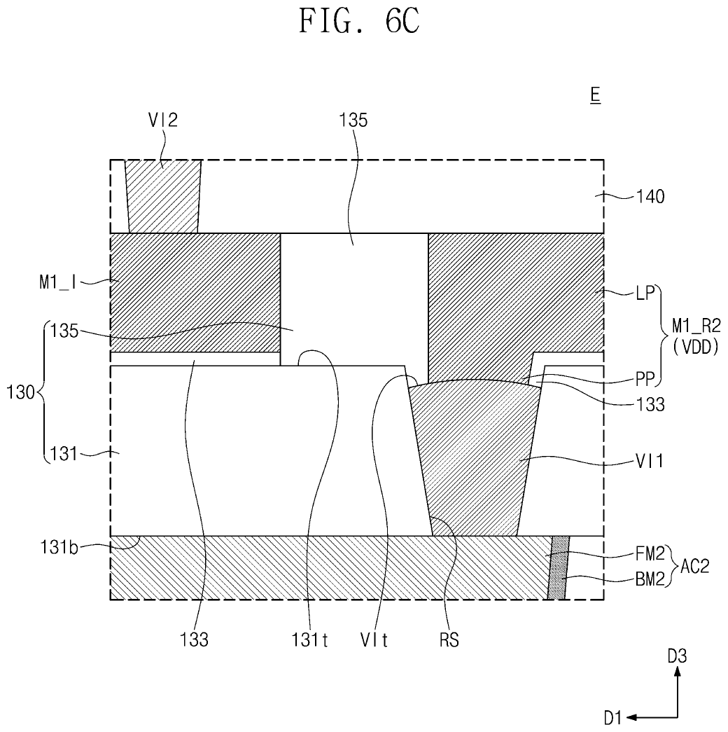

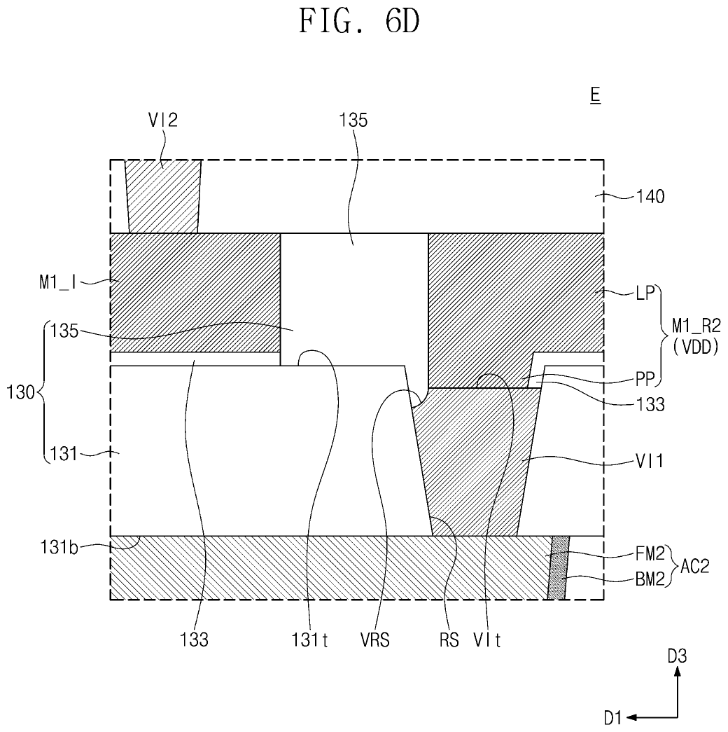

FIG. 4 illustrates a plan view showing a semiconductor device according to some embodiments of the present inventive concepts. FIGS. 5A, 5B, 5C, and 5D illustrate cross-sectional views taken along lines A-A′, B-B′, C-C′, and D-D′ of FIG. 4, respectively, showing a semiconductor device according to some embodiments of the present inventive concepts.

Referring to FIGS. 4 and 5A to 5D, a single height cell SHC may be provided on a substrate 100. The single height cell SHC may include logic transistors included in a logic circuit. The substrate 100 may be a compound semiconductor substrate or a semiconductor substrate including, for example, silicon, germanium, and/or silicon-germanium. For example, the substrate 100 may be a silicon substrate.

The substrate 100 may include a first active region AR1 and a second active region AR2. Each of the first and second active regions AR1 and AR2 may extend in the second direction D2. For example, the first active region AR1 may be an NMOSFET region, and the second active region AR2 may be a PMOSFET region.

A first active pattern AP1 and a second active pattern AP2 may be defined by a trench TR (or a device isolation layer ST in the trench TR which will be discussed below) formed on an upper portion of the substrate 100. For example, the trench TR (the device isolation layer ST) may be adjacent to the first active pattern AP1 and/or the second active pattern AP2. The first active pattern AP1 may be provided on the first active region AR1, and the second active pattern AP2 may be provided on the second active region AR2. The first and second active patterns AP1 and AP2 may extend in the second direction D2. The first and second active patterns AP1 and AP2 may be vertically protruding portions of the substrate 100. For example, the first and second active patterns AP1 and AP2 may protrude in a third direction D3. The third direction D3 may extend perpendicular to the upper surface of the substrate 100. The third direction D3 may intersect with (e.g., be perpendicular to) the first direction D1 and the second direction D2. The third direction D3 may be referred to as a vertical direction.

A device isolation layer ST may be provided on the substrate 100. The device isolation layer ST may at least partially fill the trench TR. The device isolation layer ST may include, for example, a silicon oxide layer. The device isolation layer ST may not cover any of first and second channel patterns CH1 and CH2 which will be discussed below.

A first channel pattern CHI may be provided on the first active pattern AP1. A second channel pattern CH2 may be provided on the second active pattern AP2. Each of the first and second channel patterns CHI and CH2 may include a first semiconductor pattern SP1, a second semiconductor pattern SP2, and a third semiconductor pattern SP3 that are sequentially stacked. The first, second, and third semiconductor patterns SP1, SP2, and SP3 may be spaced apart from each other in the vertical direction (e.g., the third direction D3).

Each of the first, second, and third semiconductor patterns SP1, SP2, and SP3 may include, for example, silicon (Si), germanium (Ge), and/or silicon-germanium (SiGe). For example, each of the first, second, and third semiconductor patterns SP1, SP2, and SP3 may include crystalline silicon, for example, monocrystalline silicon. According to some embodiments, the first, second, and third semiconductor patterns SP1, SP2, and SP3 may be stacked nano-sheets.

A plurality of first source/drain patterns SD1 may be provided on the first active pattern AP1. A plurality of first recesses RS1 may be formed on an upper portion of the first active pattern AP1. The first source/drain patterns SD1 may be correspondingly provided in the first recesses RS1. The first source/drain patterns SD1 may be impurity regions of a first conductivity type (e.g., n-type). The first channel pattern CHI may be interposed between the first source/drain patterns SD1 that are adjacent to each other in the second direction D2. For example, the stacked first, second, and third semiconductor patterns SP1, SP2, and SP3 of the first channel pattern CH1 may connect (e.g., electrically connect) the first source/drain patterns SD1 that are adjacent to each other in the second direction D2.

A plurality of second source/drain patterns SD2 may be provided on the second active pattern AP2. A plurality of second recesses RS2 may be formed on an upper portion of the second active pattern AP2. The second source/drain patterns SD2 may be correspondingly provided in the second recesses RS2. The second source/drain patterns SD2 may be impurity regions of a second conductivity type (e.g., p-type). The second channel pattern CH2 may be interposed between the second source/drain patterns SD2 that are adjacent to each other in the second direction D2. For example, the stacked first, second, and third semiconductor patterns SP1, SP2, and SP3 of the second channel pattern CH2 may connect (e.g., electrically connect) the second source/drain patterns SD2 that are adjacent to each other in the second direction D2.

The first and second source/drain patterns SD1 and SD2 may be epitaxial patterns formed by a selective epitaxial growth (SEG) process. For example, each of the first and second source/drain patterns SD1 and SD2 may have an upper surface higher than that of the third semiconductor pattern SP3. In some embodiments, at least one selected from the first and second source/drain patterns SD1 and SD2 may have an upper surface located at a level substantially the same as that of an upper surface of the third semiconductor pattern SP3. Hereinafter, the terms, high (higher), low (lower), and the like may refer to relative distances from the substrate 100. For example, element A higher than element B may mean that element A is disposed farther than element B from the upper surface of the substrate 100 in the vertical direction.

In some embodiments, the first source/drain patterns SD1 may include the same semiconductor element (e.g., Si) as that of the substrate 100. The second source/drain patterns SD2 may include a semiconductor element (e.g., SiGe) whose lattice constant is greater than that of a semiconductor element (e.g., Si) of the substrate 100. Therefore, the second source/drain patterns SD2 adjacent to each other in the second direction D2 may provide the second channel pattern CH2 with a compressive stress.

The second source/drain pattern SD2 may have an embossing shape at a sidewall thereof. For example, the sidewall of the second source/drain pattern SD2 may have a wavy (an uneven) profile. The sidewall of the second source/drain pattern SD2 may protrude toward first, second, and third inner electrodes PO1, PO2, and PO3 of a gate electrode GE which will be discussed below.

Gate electrodes GE may be provided on the first and second channel patterns CH1 and CH2. Etch of the gate electrodes GE may extend in the first direction D1, while running across the first and second channel patterns CHI and CH2. Each of the gate electrodes GE may vertically overlap the first and second channel patterns CH1 and CH2. The gate electrodes GE may be spaced apart from each other in the second direction D2. As used herein, “an element A overlapping an element B in a direction X” (or similar language) means that there is at least one line that extends in the direction X and intersects both the elements A and B.

Each of the gate electrodes GE may include a first inner electrode PO1 interposed between the active pattern (e.g., the first active pattern AP1 or the second active pattern AP2) and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3 (uppermost semiconductor pattern).

Each of the gate electrodes GE may extend around (e.g., surround) an upper surface TS, a lower surface BS, and opposite sidewalls SW of each of the first, second, and third semiconductor patterns SP1, SP2, and SP3. For example, a transistor according to the present embodiment may be a three-dimensional field effect transistor (e.g., Multi-Bridge-Channel (MBC) FET or Gate-All-Around (GAA) FET) in which the gate electrode GE three-dimensionally surrounds the first and second channel patterns CHI and CH2.

On the first active region AR1, inner spacers ISP may be correspondingly interposed between the first source/drain pattern SD1 and the first, second, and third inner electrodes PO1, PO2, and PO3 of the gate electrodes GE. Each of the first, second, and third inner electrodes PO1, PO2, and PO3 of the gate electrodes GE may be spaced apart from the first source/drain pattern SD1 by the inner spacer ISP. The inner spacer ISP may prevent a leakage current from the gate electrode GE.

A pair of gate spacers GS may be disposed on opposite sidewalls of the outer electrode PO4 of each of the gate electrodes GE. The gate spacers GS may extend in the first direction D1 along the gate electrode GE. For example, the gate spacers GS may include one or more of SiCN, SiCON, and SiN. In some embodiments, the gate spacers GS may include a multi-layer formed of two or more of SiCN, SiCON, and SiN. The gate spacer GS may include, for example, a silicon-containing dielectric material. The gate spacer GS may serve as an etch stop layer when first and second active contacts AC1 and AC2 are formed as discussed below. The gate spacer GS may be caused to form first and second active contacts AC1 and AC2 in a self-alignment manner.

A gate capping pattern GP may be provided on each of the gate electrodes GE. The gate capping pattern GP may extend in the first direction D1 along the gate electrode GE. The gate capping pattern GP may include a material having an etch selectivity with respect to first and second interlayer dielectric layers 110 and 120 which will be discussed below. For example, the gate capping pattern GP may include SiON, SiCN, SiCON, and/or SiN.

A gate dielectric layer GI may be interposed between the gate electrode GE and the first channel pattern CH1 and between the gate electrode GE and the second channel pattern CH2. The gate dielectric layer GI may be on (e.g., cover) the upper surface TS, the lower surface BS, and the opposite sidewalls SW of each of the first, second, and third semiconductor patterns SP1, SP2, and SP3. The gate dielectric layer GI may be on (e.g., cover) an upper surface of the device isolation layer ST below the gate electrode GE. For example, the gate dielectric layer GI may include a silicon oxide layer, a silicon oxynitride layer, and/or a high-k dielectric layer. In some embodiments, the gate dielectric layer GI may have a structure in which a silicon oxide layer and a high-k dielectric layer are stacked. The high-k dielectric layer may include a high-k dielectric material whose dielectric constant is greater than that of a silicon oxide layer. For example, the high-k dielectric material may include hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and/or lead zinc niobate.

In some embodiments, a semiconductor device according to the present inventive concepts may include a negative capacitance field effect transistor that uses a negative capacitor. For example, the gate dielectric layer GI may include a ferroelectric material layer that has ferroelectric properties and a paraelectric material layer that has paraelectric properties.

The ferroelectric material layer may have a negative capacitance, and the paraelectric material layer may have a positive capacitance. For example, when two or more capacitors are connected (e.g., electrically connected) in series, and when each capacitor has a positive capacitance, an overall capacitance may be reduced to be less than the capacitance of each capacitor. In contrast, when at least one of two or more capacitors connected in series has a negative capacitance, an overall capacitance may have a positive value that is increased to be greater than an absolute value of the capacitance of each capacitor.

When the ferroelectric material layer having a negative capacitance is connected (e.g., electrically connected) in series to the paraelectric material layer having a positive capacitance, there may be an increase in overall capacitance of the ferroelectric and paraelectric material layers that are connected in series. The increase in overall capacitance may be used to allow a transistor including the ferroelectric material layer to have a sub-threshold swing of less than about 60 mV/decade at room temperature.

The ferroelectric material layer may have ferroelectric properties. The ferroelectric material layer may include, for example, hafnium oxide, hafnium zirconium oxide, barium strontium titanium oxide, and/or lead zirconium titanium oxide. For example, the hafnium zirconium oxide may be a material in which hafnium oxide is doped with zirconium (Zr). For another example, the hafnium zirconium oxide may be a compound of hafnium (Hf), zirconium (Zr), and oxygen (O).

The ferroelectric material layer may further include impurities doped therein. For example, the impurities may include aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). The type of impurities included in the ferroelectric material layer may be changed depending on what ferroelectric material is included in the ferroelectric material layer.

When the ferroelectric material layer includes hafnium oxide, the ferroelectric material layer may include impurities such as gadolinium (Gd), silicon (Si), zirconium (Zr), aluminum (Al), and/or yttrium (Y).

When the impurities are aluminum (Al), the ferroelectric material layer may include about 3 to about 8 (e.g., 3 to 8) atomic percent aluminum. In this description, the ratio of impurities may be a ratio of aluminum to the sum of hafnium and aluminum.

When the impurities are silicon (Si), the ferroelectric material layer may include about 2 to about 10 (e.g., 2 to 10) atomic percent silicon. When the impurities are yttrium (Y), the ferroelectric material layer may include about 2 to about 10 (e.g., 2 to 10) atomic percent yttrium. When the impurities are gadolinium (Gd), the ferroelectric material layer may include about 1 to about 7 (e.g., 1 to 7) atomic percent gadolinium. When the impurities are zirconium (Zr), the ferroelectric material layer may include about 50 to about 80 (e.g., 50 to 80) atomic percent zirconium.

The paraelectric material layer may have paraelectric properties. The paraelectric material layer may include, for example, silicon oxide and/or high-k metal oxide. The high-k metal oxide included in the paraelectric material layer may include, for example, hafnium oxide, zirconium oxide, and/or aluminum oxide, but the present inventive concepts are not limited thereto.

The ferroelectric and paraelectric material layers may include the same material. The ferroelectric material layer may have ferroelectric properties, but the paraelectric material layer may not have ferroelectric properties. For example, when the ferroelectric material layer and a paraelectric material include hafnium oxide, a crystal structure of hafnium oxide included in the ferroelectric material layer may be different from that of hafnium oxide included in the paraelectric material layer.

The ferroelectric material layer may have a thickness having ferroelectric properties. The thickness of the ferroelectric material layer may range, for example, from about 0.5 nm to about 10 nm (e.g., 0.5 nm to 10 nm), but the present inventive concepts are not limited thereto. Because ferroelectric materials have their own critical thickness that exhibits ferroelectric properties, the thickness of the ferroelectric material layer may depend on ferroelectric material.

For example, the gate dielectric layer GI may include one ferroelectric material layer. For another example, the gate dielectric layer GI may include a plurality of ferroelectric material layers that are spaced apart from each other. The gate dielectric layer GI may have a stack structure in which a plurality of ferroelectric material layers are alternately stacked with a plurality of paraelectric material layers.

A first interlayer dielectric layer 110 may be provided on the substrate 100. The first interlayer dielectric layer 110 may extend around (e.g., cover) the gate spacers GS and the first and second source/drain patterns SD1 and SD2. The first interlayer dielectric layer 110 may have an upper surface substantially coplanar with that of the gate capping pattern GP and that of the gate spacer GS.

A second interlayer dielectric layer 120 may be disposed on the first interlayer dielectric layer 110. A third interlayer dielectric layer 130 may be provided on the second interlayer dielectric layer 120. A fourth interlayer dielectric layer 140 may be provided on the third interlayer dielectric layer 130. For example, the first, second, third, and fourth interlayer dielectric layers 110, 120, 130, and 140 may include a silicon oxide layer.

The single height cell SHC may have a first boundary BD1 and a second boundary BD2 that are opposite to each other in the second direction D2. Each of the first and second boundaries BD1 and BD2 may extend in the first direction D1. The single height cell SHC may have a third boundary BD3 and a fourth boundary BD4 that are opposite to each other in the first direction D1. Each of the third and fourth boundaries BD3 and BD4 may extend in the second direction D2.

The single height cell SHC may be provided on its opposite sides with a pair of separation structures DB that are opposite to each other in the second direction D2. For example, the pair of separation structures DB may be correspondingly provided on the first and second boundaries BD1 and BD2 of the single height cell SHC. The separation structure DB may extend in the first direction D1 parallel to the gate electrodes GE.

The separation structure DB may penetrate the first and second interlayer dielectric layers 110 and 120 to extend (at least partially) into the first and second active patterns AP1 and AP2. The separation structure DB may penetrate an upper portion of each of the first and second active patterns AP1 and AP2. The separation structure DB may electrically separate an active region (e.g., the first active pattern AP1 and/or the second active pattern AP2) of the single height cell SHC from an active region of an adjacent another cell.

First and second active contacts AC1 and AC2 may be provided to at least partially penetrate the first and second interlayer dielectric layers 110 and 120 to be respectively electrically connected to the first and second source/drain patterns SD1 and SD2. The gate electrode GE may be positioned between the first active contacts AC1 that are adjacent to each other in the second direction D2 and between the second active contacts AC2 that are adjacent to each other in the second direction D2. When viewed in plan, each of the first and second active contacts AC1 and AC2 may have a bar shape that extends in the first direction D1.

The first active contact AC1 may include a first conductive pattern FM1 and a first barrier pattern BM1 that extends around (e.g., at least partially surrounds) the first conductive pattern FM1. The first barrier pattern BM1 may cover sidewalls and a lower surface of the first conductive pattern FM1. For example, the first conductive pattern FM1 may include aluminum, copper, tungsten, molybdenum, and/or cobalt. The first barrier pattern BM1 may be a metal layer including titanium, tantalum, tungsten, nickel, cobalt, and/or platinum or a metal nitride layer including titanium nitride (TiN), tantalum nitride (TaN), tungsten nitride (WN), nickel nitride (NiN), cobalt nitride (CON), and/or platinum nitride (PtN). The second active contact AC2 may include a second conductive pattern FM2 and a second barrier pattern BM2 that extends around (e.g., at least partially surrounds) the second conductive pattern FM2. The second active contact AC2 may be substantially the same as (e.g., may include the same material as that of) the first active contact AC1.

Each of the first and second active contacts AC1 and AC2 may be a self-aligned contact. For example, the gate capping pattern GP and the gate spacer GS may be used to form the first and second active contacts AC1 and AC2 in a self-alignment manner. The first and second active contacts AC1 and AC2 may be disposed adjacent to a sidewall of the gate spacer GS. In some embodiments, the first and second active contacts AC1 and AC2 may be on (e.g., cover) a portion of the upper surface of the gate capping pattern GP.

A metal-semiconductor compound layer SC may be provided between the first active contact AC1 and the first source/drain pattern SD1 and between the second active contact AC2 and the second source/drain pattern SD2. The first and second active contacts AC1 and AC2 may be electrically connected through the metal-semiconductor compound layers SC to the first and second source/drain patterns SD1 and SD2, respectively. For example, the metal-semiconductor compound layer SC may include titanium silicide, tantalum silicide, tungsten silicide, nickel silicide, and/or cobalt silicide.

A gate contact GC may be provided to penetrate the second interlayer dielectric layer 120 and the gate capping pattern GP to be electrically connected to the gate electrode GE.

The gate contact GC may include a conductive pattern FM and a barrier pattern BM that extends around (e.g., at least partially surrounds) the conductive pattern FM. The barrier pattern BM may cover sidewalls and a lower surface of the conductive pattern FM. The conductive pattern FM may be substantially the same as (e.g., may include the same material as those of) the first and second conductive patterns FM1 and FM2 of the first and second active contacts AC1 and AC2. The barrier pattern BM may be substantially the same as (e.g., may include the same material as those of) the first and second barrier patterns BM1 and BM2 of the first and second active contacts AC1 and AC2. When viewed in plan, the gate contact GC may be disposed to overlap a corresponding one of the first active region AR1 and the second active region AR2. For example, the gate contact GC may be provided on the second active pattern AP2.

A first metal layer M1 may be provided in the third interlayer dielectric layer 130. For example, the first metal layer M1 may include a first power line M1_R1, a second power line M1_R2, and first wiring lines M1_I. The lines M1_R1, M1_R2, and M1_I of the first metal layer M1 may parallelly extend in the second direction D2.

For example, the first and second power lines M1_R1 and M1_R2 may be respectively provided on the third and fourth boundaries BD3 and BD4 of the single height cell SHC. The first power line M1_R1 may extend in the second direction D2 along the third boundary BD3. The second power line M1_R2 may extend in the second direction D2 along the fourth boundary BD4.

The first wiring lines M1_I of the first metal layer M1 may be disposed between the first and second power lines M1_R1 and M1_R2. The first wiring lines M1_I of the first metal layer M1 may be spaced apart from each other in the first direction D1. Each of the first wiring lines M1_I may have a line-width (e.g., a line-width in the first direction D1) less than that of each of the first and second power lines M1_R1 and M1_R2.

The first metal layer M1 may further include first vias VI1. The first vias VII may be provided below the lines M1_R1, M1_R2, and/or M1_I of the first metal layer M1. The first active contact AC1, the second active contact AC2, and the gate contact GC may be electrically connected through the first vias VII to the lines M1_R1, M1_R2, and/or M1_I of the first metal layer M1.

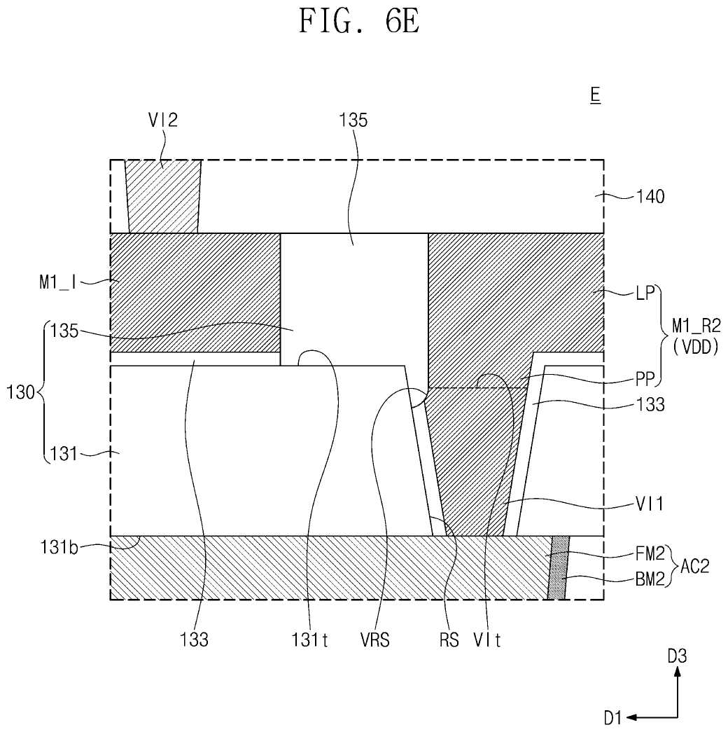

The lines M1_R1, M1_R2, and M1_I and its underling first via VII of the first metal layer M1 may be formed by processes independently of each other. The lines M1_R1, M1_R2, and M1_I and the first via VII of the first metal layer M1 will be further discussed in detail below with reference to FIGS. 6A and 6B.

A second metal layer M2 may be provided in the fourth interlayer dielectric layer 140. The second metal layer M2 may include a plurality of second wiring lines M2_I. The second wiring lines M2_I of the second metal layer M2 may each have a linear or bar shape that extends in the first direction D1. The second wiring lines M2_I may parallel extend in the first direction D1 and may be spaced apart from each other in the second direction D2.

The second metal layer M2 may further include second vias VI2 that are correspondingly provided below the second wiring lines M2_I. A line (e.g., the lines M1_R1, M1_R2, and/or M1_I) of the first metal layer M1 may be electrically through the second via VI2 to a corresponding line (e.g., the second wiring lines M2_I) of the second metal layer M2. A certain line and its underlying second via VI2 of the second metal layer M2 may be simultaneously formed by a dual damascene process.

FIGS. 6A to 6E illustrate enlarged views of section E depicted in FIG. 5C, showing a semiconductor device according to some embodiments of the present inventive concepts.

Referring to FIG. 6A, the third interlayer dielectric layer 130 may include a lower interlayer dielectric layer 131 and an upper interlayer dielectric layer 135. The lower interlayer dielectric layer 131 may be positioned on the second interlayer dielectric layer 120 and the second active contact AC2. The upper interlayer dielectric layer 135 may be positioned on the lower interlayer dielectric layer 131. The fourth interlayer dielectric layer 140 may be positioned on the upper interlayer dielectric layer 135.

The lower interlayer dielectric layer 131 may have a recess RS. The recess RS may penetrate the lower interlayer dielectric layer 131 to expose a sidewall of the lower interlayer dielectric layer 131. For example, a width (e.g., a width in the first direction D1 or a width in the second direction D2) of the recess RS may be changed in the third direction D3. The width of the recess RS may increase in a direction from a lower surface 131b of the lower interlayer dielectric layer 131 toward an upper surface 131t of the lower interlayer dielectric layer 131. In some embodiments, the width of the recess RS may be constant along the third direction D3.

The first via VI1 may be positioned in the recess RS of the lower interlayer dielectric layer 131. An upper surface VIt of the first via VI1 may be located at a level lower than that of the upper surface 131t of the lower interlayer dielectric layer 131. For example, the upper surface VIt of the first via VI1 may not be positioned on the same plane as that of the upper surface 131t of the lower interlayer dielectric layer 131. The first via VI1 may partially fill the recess RS. The first via VI1 may fill a lower portion of the recess RS in the lower interlayer dielectric layer 131. Thus, an inner wall (e.g., inner sidewall) of the recess RS may be partially exposed by the first via VI1. For example, an upper portion of the inner wall of the recess RS may be exposed by the first via VI1. The first via VI1 may have a first length L1 in the first direction DI at the upper surface VIt thereof. The first length L1 may be an upper width of the first via VI1. For example, the first length L1 may range from about 5 nm to about 15 nm (e.g., from 5 nm to 15 nm). The first via VI1 may include, for example, metallic material, such as aluminum (Al), copper (Cu), tungsten (W), molybdenum (Mo), ruthenium (Ru), and/or cobalt (Co), and may include, for example, ruthenium (Ru) and/or molybdenum (Mo).

The second power line M1_R2 may be positioned on the lower interlayer dielectric layer 131 and the first via VI1. The second power line M1_R2 may be connected (e.g., electrically connected) to the first via VI1. The second power line M1_R2 may include a line portion LP and a protrusion portion PP. The protrusion portion PP may vertically extend from and be positioned below the line portion LP. The line portion LP may be positioned on the upper surface 131t of the lower interlayer dielectric layer 131, and the protrusion portion PP may be at least partially positioned in the recess RS of the lower interlayer dielectric layer 131. For example, the protrusion portion PP may contact the upper surface VIt of the first via VI1, while at least partially filling an upper portion of the recess RS.

The first wiring line M1_I may be positioned on the lower interlayer dielectric layer 131. The first wiring line M1_I may be spaced apart in the first direction DI at a second length L2 from the second power line M1_R2. The second length L2 may be an interval between the lines M1_R1, M1_R2, and M1_I of the first metal layer M1 depicted in FIG. 4. For example, the second length L2 may range from about 10 nm to about 20 nm (e.g., from 10 nm to 20 nm). Likewise the second power line M1_R2, the first wiring line M1_I may include a line portion and a protrusion portion that vertically extends from the line portion. The first wiring line M1_I shown in the drawings may correspond to the line portion of the first wiring line M1_I. The line portion of the first wiring line M1_I may be vertically and horizontally spaced apart from the upper surface VIt of the first via VI1.

The second power line M1_R2 and the first wiring line M1_I of the first metal layer M1 may include, for example, aluminum (Al), copper (Cu), tungsten (W), molybdenum (Mo), ruthenium (Ru), and/or cobalt (Co), and may include, for example, ruthenium (Ru).

An adhesion layer 133 may be positioned between the second power line M1_R2 and the lower interlayer dielectric layer 131 and between the first wiring line M1_I and the lower interlayer dielectric layer 131. For example, the adhesion layer 133 may not be positioned on the upper surface 131t of the lower interlayer dielectric layer 131 on which the first wiring line M1_I is not provided. The adhesion layer 133 (e.g., a sidewall of the adhesion layer 133) may be aligned with a sidewall of the first wiring line M1_I. The adhesion layer 133 may have a sidewall aligned with one sidewall of the first wiring line M1_I. The adhesion layer 133 may be positioned between the lower interlayer dielectric layer 131 and the line portion LP of the second power line M1_R2 and between the recess RS (e.g., an inner wall (an upper portion of the inner wall) of the recess RS) and the protrusion portion PP of the second power line M1_R2. The adhesion layer 133 between the lower interlayer dielectric layer 131 and the second power line M1 R2 connected to the first via VI1 may extend from the upper surface 131t of the lower interlayer dielectric layer 131 to a portion of the inner wall of the recess RS. For example, a portion of the adhesion layer 133 may cover a portion of the inner wall (e.g., an upper portion of the inner wall) of the recess RS.

The adhesion layer 133 may have excellent adhesive force to the lower interlayer dielectric layer 131. In addition, the adhesion layer 133 may have superior adhesive force to the first wiring line M1_I and the second power line M1_R2 of the first metal layer M1. Thus, the adhesion layer 133 may prevent the first wiring line M1_I and the second power line M1_R2 from delamination (separating) from the lower interlayer dielectric layer 131. The adhesion layer 133 may include a dielectric material, such as silicon (Si), oxygen (O), carbon (C), aluminum (Al), titanium (Ti), and/or tantalum (Ta).

The present inventive concepts, however, are not limited to that discussed above. As shown in FIGS. 5A to 5D, the first via VI1 may be connected to the first power line M1_R1 and/or the first wiring line M1_I of the first metal layer M1. In this case, the first power line M1_R1 and the first wiring line M1_I connected to the first via VI1 may include a line portion LP on the upper surface 131t of the lower interlayer dielectric layer 131 and a protrusion portion PP in the recess RS. For example, the lines M1_R1, M1_R2, and M1_I of the first metal layer M1 that are connected to the first via VI1 may include a line portion LP and a protrusion portion PP. In addition, the adhesion layer 133 may be positioned between the lower interlayer dielectric layer 131 and the lines M1_R1, M1_R2, and M1_I of the first metal layer M1. For example, the adhesion layer 133 may be positioned between the lower interlayer dielectric layer 131 and the lines M1_R1, M1_R2, and/or M1_I of the first metal layer M1 in a similar manner as described in FIGS. 6A to 6E.

The upper interlayer dielectric layer 135 may be positioned between the second power line M1_R2 and the first wiring line M1_I. A portion of the upper interlayer dielectric layer 135 may be positioned in the recess RS, but the present inventive concepts are not limited thereto. An upper surface of the upper interlayer dielectric layer 135 may be coplanar with that of the first wiring line M1_I and that of the second power line M1_R2.

Referring to FIG. 6B, the adhesion layer 133 may entirely cover the upper surface 131t of the lower interlayer dielectric layer 131. On the upper surface 131t of the lower interlayer dielectric layer 131, the adhesion layer 133 may be positioned between the first wiring line M1_I and the second power line M1_R2. For example, on the upper surface 131t of the lower interlayer dielectric layer 131, the adhesion layer 133 may extend between the first wiring line M1_I and the second power line M1_R2. Irrespective of the first wiring line M1_I and the second power line M1_R2, the adhesion layer 133 may extend from the upper surface 131t of the lower interlayer dielectric layer 131 to a portion of the inner wall of the recess RS. For example, the adhesion layer 133 may be disposed on upper portions of opposite inner walls (e.g., opposite sidewalls) of the recess RS. For example, the adhesion layer 133 may not be patterned in a procedure for forming the second power line M1_R2 and the first wiring line M1_I.

Referring to FIG. 6C, the upper surface VIt of the first via VI1 may have a shape that is convex toward the second power line M1_R2. When the first via VI1 is formed through selective area growth (SAG), the upper surface VIt of the first via VI1 may have a convex shape, but the present inventive concepts are not limited thereto.

In this configuration, the upper surface VIt of the first via VI1 may be located at a maximum (e.g., an uppermost or a highest) level at a center region of the first via VI1 along the first direction D1. The upper surface VIt of the first via VI1 may be located at a minimum (e.g., a lowermost or a lowest) level at an edge of the first via VI along the first direction D1. The upper surface VIt of the first via VI1 may not be parallel to the upper surface 131t of the lower interlayer dielectric layer 131. A lower surface of the protrusion portion PP of the second power line M1_R2 may have a shape that is concave toward the lower surface 131b of the lower interlayer dielectric layer 131.

Referring to FIG. 6D, the first via VI1 may have a via recess VRS. The via recess VRS may penetrate a portion of the first via VI1 from the upper surface VIt of the first via VI1. The via recess VRS may be in contact with an inner wall of the recess RS on which the adhesion layer 133 is not provided. For example, a portion of inner wall of the recess RS may be a portion of inner wall of the via recess VRS. Therefore, the via recess VRS may outwardly expose at least a portion of the inner wall of the recess RS. The upper interlayer dielectric layer 135 may fill a portion of the recess RS and the via recess VRS.

In this configuration, the via recess VRS may be formed on the upper surface VIt of the first via VI1 on which the second power line M1_R2 is not provided. For example, the via recess VRS may extend from one lateral surface (e.g., a sidewall) of the second power line M1_R2. When viewed in plan, the via recess VRS may not overlap the second power line M1_R2 (in the vertical direction).

Referring to FIG. 6E, the first via VI1 and the second power line M1_R2 may include the same metallic material. For example, the first via VI1 and the second power line M1_R2 may be formed by their own processes. In this case, a visible interface VIt may be provided between the first via VI1 and the second power line M1_R2, and the interface VIt may be the same as the upper surface VIt of the first via VI1.

In some embodiments, the first via VI1 and the second power line M1_R2 may be formed simultaneously with each other, and may be integrally connected into a single object. In this case, an invisible interface VIt (or no interface) may be provided between the first via VI1 and the second power line M1_R2. A single object herein may refer to a structure without a visible interface or without an interface between two sub-structures thereof.

As the adhesion layer 133 is provided between the second power line M1_R2 and the lower interlayer dielectric layer 131, and as the second power line M1_R2 and the first via VI1 are integrally connected into a single object, the adhesion layer 133 may be provided between the first via VI1 and the lower interlayer dielectric layer 131. For example, the adhesion layer 133 may extend from the upper surface 131t to the lower surface 131b of the lower interlayer dielectric layer 131, while covering at least a portion of the inner wall of the recess RS. The adhesion layer 133 may not cover the lower surface 131b of the lower interlayer dielectric layer 131.

Likewise, as shown in FIG. 6D, the first via VI1 may have a via recess VRS. A portion of the adhesion layer 133 may be removed while the via recess VRS is formed. For example, the via recess VRS may cause the adhesion layer 133 to cover a portion of the inner wall of the recess RS, and a portion of the inner wall of the recess RS that the adhesion layer 133 does not cover may be outwardly exposed.

Referring back to FIGS. 5A to 6E, the adhesion layer 133 may be provided between the lower interlayer dielectric layer 131 and the lines M1_R1, M1_R2, and M1_I of the first metal layer M1, and may not be provided between the first via VI1 and the lines M1_R1, M1_R2, and M1_I of the first metal layer M1. In some embodiments, the first via VI1 and each of the lines M1_R1, M1_R2, and M1_I of the first metal layer M1 may be formed into a single object. For example, the adhesion layer 133 of the present inventive concepts may be excluded between the first via VI1 and the lines M1_R1, M1_R2, and M1_I of the first metal layer M1. Therefore, it may be possible to prevent the resistance between the first via VI1 and the lines M1_R1, M1_R2, and M1_I of the first metal layer M1 from increasing as the adhesion layer 133 is excluded therebetween. As a result, a semiconductor device may improve in electrical properties.

In addition, as the upper surface VIt of the first via VI1 is located at a level lower than that of the upper surface 131t of the lower interlayer dielectric layer 131, a sufficient interval may be obtained between the first via VI1 and the lines M1_R1, M1_R2, and M1_I of the first metal layer M1 each of which is adjacent to but not connected to the first via VI1. Each of the lines M1_R1, M1_R2, and M1_I of the first metal layer M1 may include a line portion LP and a protrusion portion PP, and the line portion LP may be vertically spaced apart from the upper surface VIt of the first via VI1. Therefore, it may be possible to form a small interval between the lines M1_R1, M1_R2, and M1_I of the first metal layer M1, and also to prevent an unintended electrical connection between the lines M1_R1, M1_R2, and M1_I of the first metal layer M1. Accordingly, a semiconductor device may have increased integration and improved electrical properties.

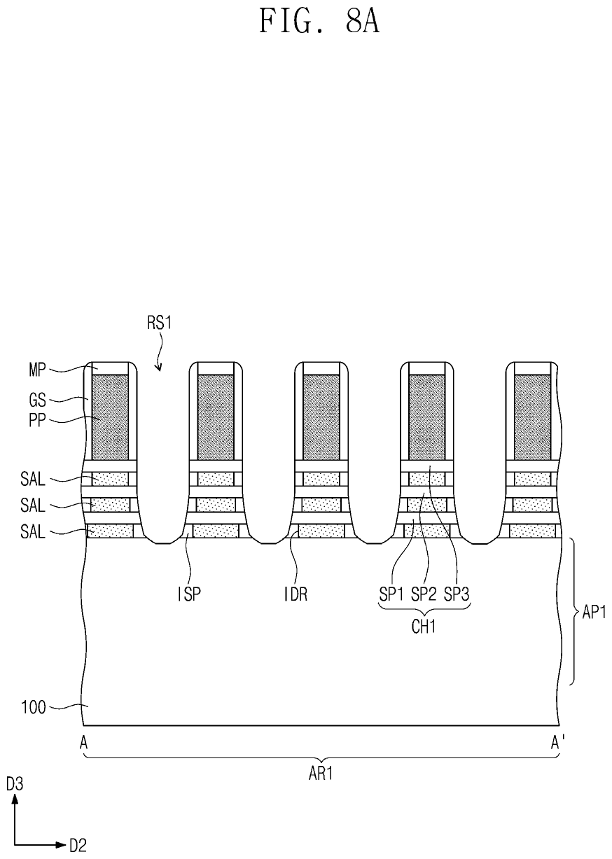

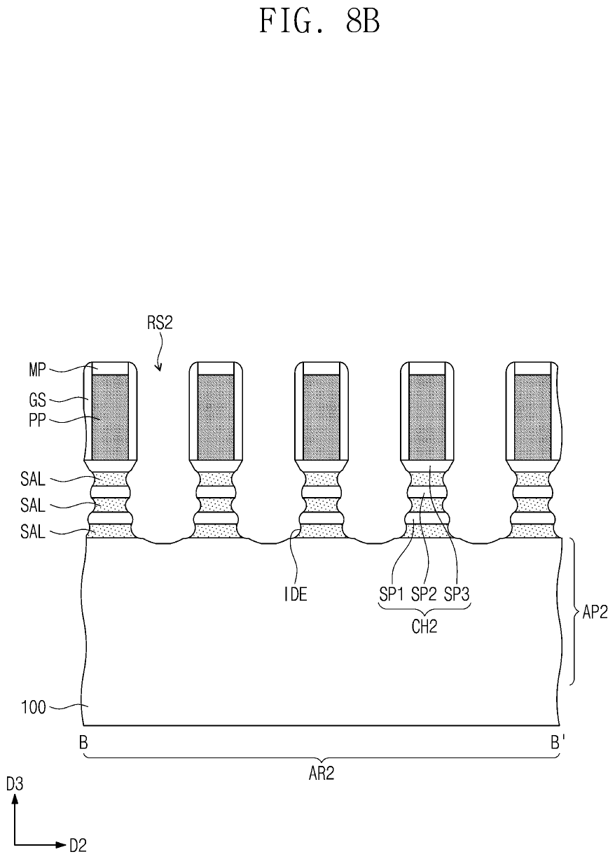

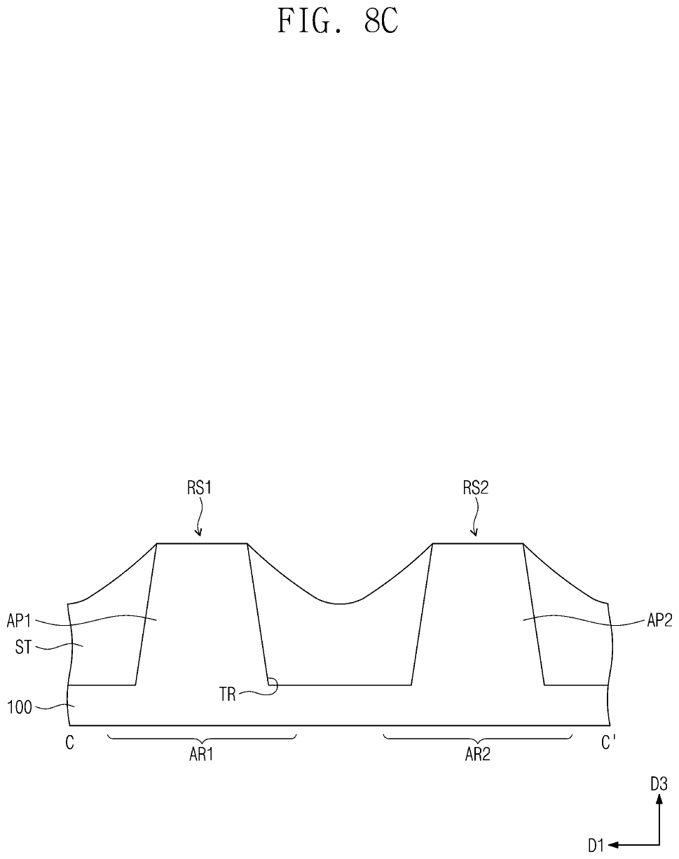

FIGS. 7A to 15D illustrate cross-sectional views showing a method of fabricating a semiconductor device according to some embodiments of the present inventive concepts. FIGS. 7A, 8A, 9A, 10A, 11A, 12A, 13A, 14A, and 15A illustrate cross-sectional views taken along line A-A′ of FIG. 4. FIGS. 8B, 9B, 10B, 11B, 12B, 13B, 14B, and 15B illustrate cross-sectional views taken along line B-B′ of FIG. 4. FIGS. 8C, 9C, 10C, 11C, 12C, 13C, 14C, and 15C illustrate cross-sectional views taken along line C-C′ of FIG. 4. FIGS. 7B, 9D, 10D, 11D, 12D, 13D, 14D, and 15D illustrate cross-sectional views taken along line D-D′ of FIG. 4.

Referring to FIGS. 7A and 7B, a substrate 100 may be provided which includes a first active region AR1 and a second active region AR2. Active layers ACL and sacrificial layers SAL may be alternately stacked on the substrate 100. For example, the active layers ACL may include one of silicon (Si), germanium (Ge), and silicon-germanium (SiGe), and the sacrificial layers SAL may include another of silicon (Si), germanium (Ge), and silicon-germanium (SiGe).

The sacrificial layer SAL may include a material having an etch selectivity with respect to the active layer ACL. For example, the active layers ACL may include silicon (Si), and the sacrificial layers SAL may include silicon-germanium (SiGe). Each of the sacrificial layers SAL may have a germanium concentration of about 10 at % to about 30 at % (e.g., 10 at % to 30 at %).

Mask patterns may be formed on each of the first and second active regions AR1 and AR2 of the substrate 100. The mask pattern may have a linear or bar shape that extends in a second direction D2.

A patterning process may be performed in which the mask pattern is used to form a trench TR that defines a first active pattern AP1 and a second active pattern AP2. The first active pattern AP1 may be formed on the first active region AR1. The second active pattern AP2 may be formed on the second active region AR2.

A stack pattern STP may be formed on each of the first and second active patterns AP1 and AP2. The stack pattern STP may include the active layers ACL and the sacrificial layers SAL that are alternately stacked. During the patterning process, the stack pattern STP may be formed simultaneously with the first and second active patterns AP1 and AP2.

Thereafter, a device isolation layer ST may be formed to fill (e.g., at least partially fill) the trench TR. The formation of the device isolation layer ST may include forming a dielectric layer covering the first and second active patterns AP1 and AP2 and the stack patterns STP on the upper surface of the substrate 100, and recessing the dielectric layer until the stack patterns STP are exposed.

The device isolation layer ST may include a dielectric material, such as a silicon oxide layer. The stack patterns STP may be exposed upwardly from the device isolation layer ST. The stack patterns STP may vertically protrude upwards from the device isolation layer ST.

Referring to FIGS. 8A to 8C, sacrificial patterns PP running across the stack patterns STP may be formed on the substrate 100. The sacrificial patterns PP may be formed to each have a linear or bar shape that extends in a first direction D1. The sacrificial patterns PP may be spaced apart from each other in the second direction D2.

For example, the formation of the sacrificial patterns PP may include forming a sacrificial layer on the upper surface of the substrate 100, forming hardmask patterns MP on the sacrificial layer, and using the hardmask patterns MP as an etching mask to pattern the sacrificial layer. The sacrificial layer may include, for example, polysilicon.

A pair of gate spacers GS may be formed on opposite sidewalls of each of the sacrificial patterns PP. The formation of the gate spacers GS may include conformally forming a gate spacer layer on the upper surface of the substrate 100 and anisotropically etching the gate spacer layer. For example, the gate spacer GS may be a multiple layer including at least two layers.

Afterwards, first recesses RS1 may be formed in the stack pattern STP on the first active pattern AP1. Second recesses RS2 may be formed in the stack pattern STP on the second active pattern AP2. During the formation of the first and second recesses RS1 and RS2, the device isolation layer ST may be further recessed on opposite sides of each of the first and second active patterns AP1 and AP2.

For example, the hardmask patterns MP and the gate spacers GS may be used as an etching mask such that the stack pattern STP on the first active pattern AP1 may be etched to form the first recesses RS1. The first recess RS1 may be formed between the sacrificial patterns PP that are adjacent to each other in the second direction D2. A width in the second direction D2 of the first recess RS1 may decrease with decreasing distance (in the vertical direction perpendicular to an upper surface of the substrate 100 (e.g., the third direction D3)) from the substrate 100.

Sequentially stacked first, second, and third semiconductor patterns SP1, SP2, and SP3 may be correspondingly formed from the active layers ACL between the first recesses RS1 that are adjacent to each other in the second direction D2. A first channel pattern CHI may include the first, second, and third semiconductor patterns SP1, SP2, and SP3 between the first recesses RS1 that are adjacent to each other in the second direction D2.

The first recess RS1 may expose the sacrificial layers SAL. A selective etching process may be performed on the exposed sacrificial layers SAL. The etching process may include a wet etching process that selectively etches only silicon-germanium. In the etching process, each of the sacrificial layers SAL may be indented to form an indent region IDR. The indent region IDR may allow the sacrificial layer SAL to have a concave sidewall. A dielectric layer may be formed in the first recess RS1 to fill the indent regions IDR. The sacrificial layers SAL and the first, second, and third semiconductor patterns SP1, SP2, and SP3 exposed by the first recess RS1 may become a seed layer for the dielectric layer (also referred to as an epitaxial dielectric layer). The dielectric layer may be a crystalline dielectric layer grown on a crystalline semiconductor included in the sacrificial layers SAL and the first, second, and third semiconductor patterns SP1, SP2, and SP3.

An inner spacer ISP may be formed to fill (e.g., at least partially fill) the indent region IDR. For example, the formation of the inner spacer ISP may include wet-etching the epitaxial dielectric layer until sidewalls of the first, second, and third semiconductor patterns SP1, SP2, and SP3 are exposed. Therefore, the epitaxial dielectric layer may remain only in the indent region IDR, thereby constituting the inner spacer ISP.

The second recesses RS2 in the stack pattern STP on the second active pattern AP2 may be formed by a method similar to that used for forming the first recesses RS1. The sacrificial layers SAL exposed by the second recess RS2 may undergo a selective etching process to form indent regions IDE on the second active pattern AP2. The indent regions IDE may cause the second recess RS2 to have a wavy inner sidewall (e.g., an uneven inner sidewall). The inner spacers ISP may not be formed in the indent regions IDE on the second active pattern AP2. A second channel pattern CH2 may be constituted by the first, second, and third semiconductor patterns SP1, SP2, and SP3 between neighboring (e.g., adjacent) second recesses RS2.

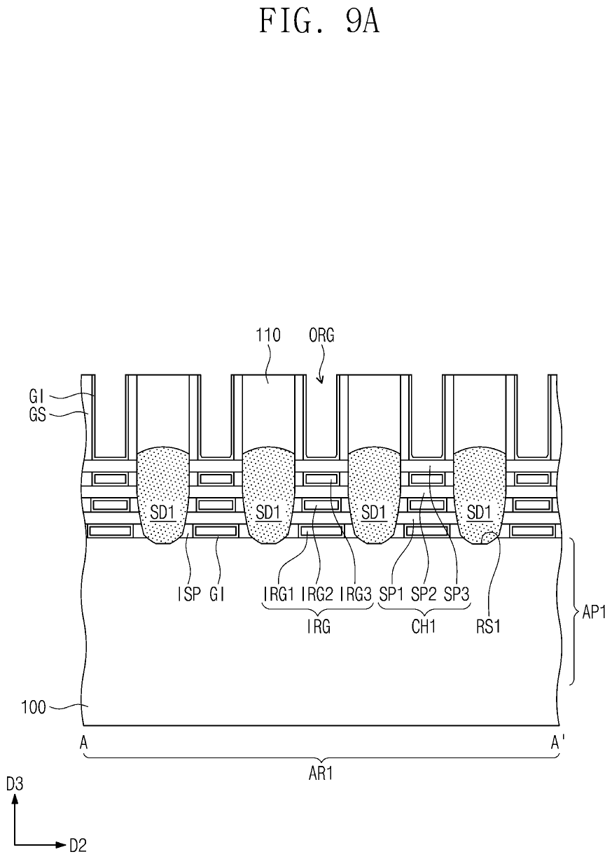

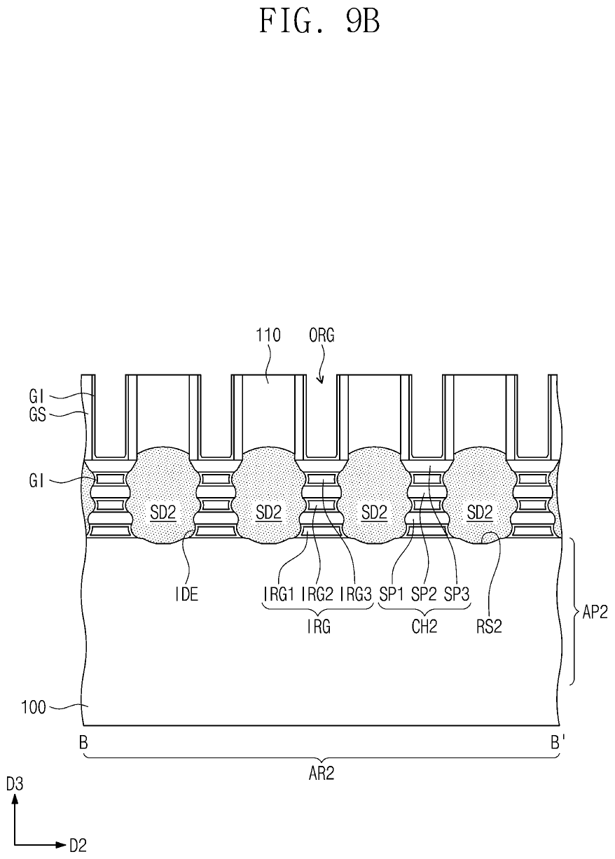

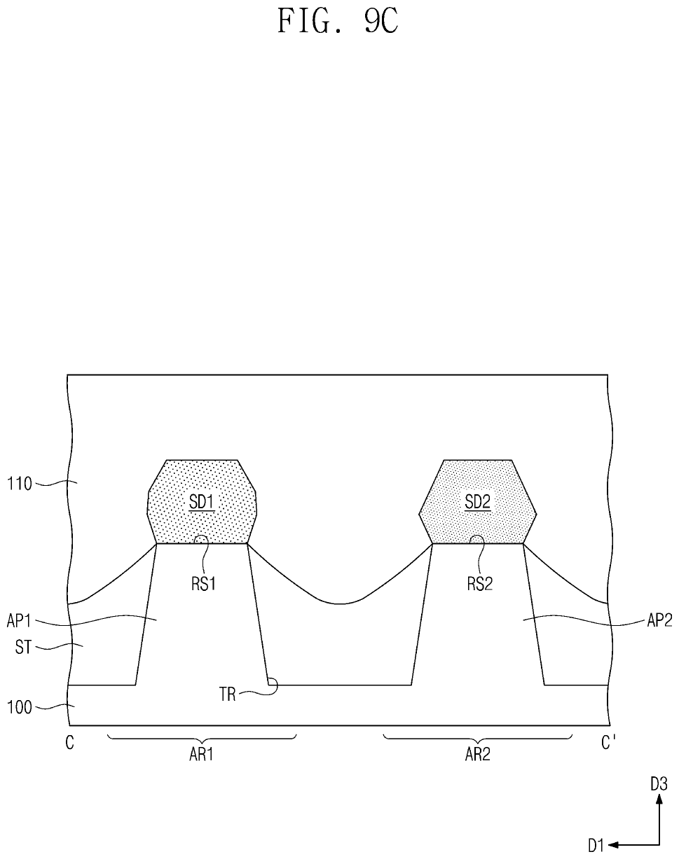

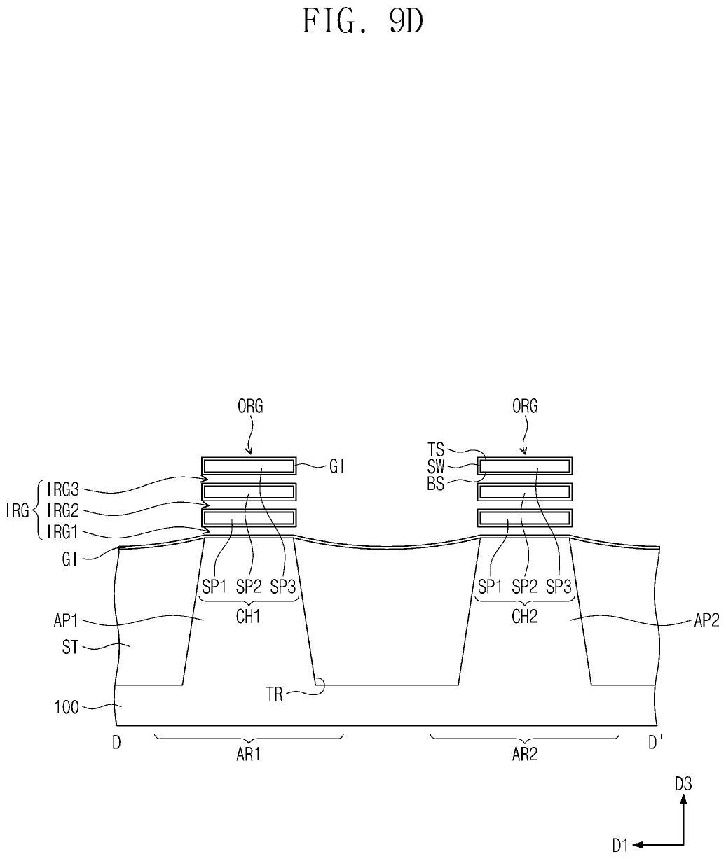

Referring to FIGS. 9A to 9D, first source/drain patterns SD1 may be correspondingly formed in the first recesses RS1. For example, a selective epitaxial growth (SEG) process may be performed in which an inner sidewall of the first recess RS1 is used as a seed layer to form an epitaxial layer that (at least partially) fills the first recess RS1. The epitaxial layer may be grown from a seed, or the substrate 100 and the first, second, and third semiconductor patterns SP1, SP2, and SP3 that are exposed by the first recess RS1. For example, the selective epitaxial growth process may include chemical vapor deposition (CVD) or molecular beam epitaxy (MBE).

For example, the first source/drain patterns SD1 may be formed of the same semiconductor element (e.g., Si) as that of the substrate 100. While the first source/drain pattern SD1 is formed, impurities (e.g., phosphorus, arsenic, and/or antimony) may be in-situ implanted to allow the first source/drain pattern SDI to have, for example, an n-type conductivity type. In some embodiments, after the first source/drain pattern SD1 is formed, impurities may be implanted into the first source/drain pattern SD1.

Second source/drain patterns SD2 may be correspondingly formed in the second recesses RS2. For example, the formation of the second source/drain patterns SD2 may include performing a selective epitaxial growth process in which inner sidewalls of the second recesses RS2 are used as seed layers.

For example, the second source/drain patterns SD2 may include a semiconductor element (e.g., SiGe) whose lattice constant is greater than that of a semiconductor element (e.g., Si) of the substrate 100. While the second source/drain pattern SD2 is formed, impurities (e.g., boron, gallium, or indium) may be in-situ implanted to allow the second source/drain pattern SD2 to have, for example, a p-type conductivity type. In some embodiments, after the second source/drain pattern SD2 is formed, impurities may be implanted into the second source/drain pattern SD2.

A first interlayer dielectric layer 110 may be formed on (e.g., to cover) the first and second source/drain patterns SD1 and SD2, the hardmask patterns MP, and the gate spacers GS. For example, the first interlayer dielectric layer 110 may include a silicon oxide layer.

The first interlayer dielectric layer 110 may be planarized until upper surfaces of the sacrificial patterns PP are exposed. An etch-back or chemical mechanical polishing (CMP) process may be used to planarize the first interlayer dielectric layer 110. During the planarization process, the hardmask patterns MP may all be removed. As a result, the first interlayer dielectric layer 110 may have an upper surface coplanar with those of the sacrificial patterns PP and those of the gate spacers GS.

The exposed sacrificial patterns PP may be selectively removed. The removal of the sacrificial patterns PP may form an outer region ORG that exposes the first and second channel patterns CH1 and CH2. The removal of the sacrificial patterns PP may include performing a wet etching process that uses an etchant capable of selectively etching polysilicon.

The sacrificial layers SAL exposed through the outer region ORG may be selectively removed to form inner regions IRG. For example, the inner region IRG may include first, second, and third inner regions IRG1, IRG2, and IRG3. The first inner region IRG1 may be formed between the first active pattern AP1 and the first semiconductor pattern SP1 or between the second active pattern AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

For example, only the sacrificial layers SAL may be removed while leaving the first, second, and third semiconductor patterns SP1, SP2, and SP3. For example, the etching process may have a high etch rate with respect to silicon-germanium having relatively high germanium concentration. In this case, the etching process may have a high etch rate with respect to silicon-germanium whose germanium concentration is equal to or greater than about 10 at % (e.g., 10 at %).

A gate dielectric layer GI may be formed on the exposed first, second, and third semiconductor patterns SP1, SP2, and SP3. The gate dielectric layer GI may be formed to extend around (e.g., at least partially surround) each of the first, second, and third semiconductor patterns SP1, SP2, and SP3. The gate dielectric layer GI may be formed in each of the first, second, and third inner regions IRG1, IRG2, and IRG3. The gate dielectric layer GI may be formed in the outer region ORG.

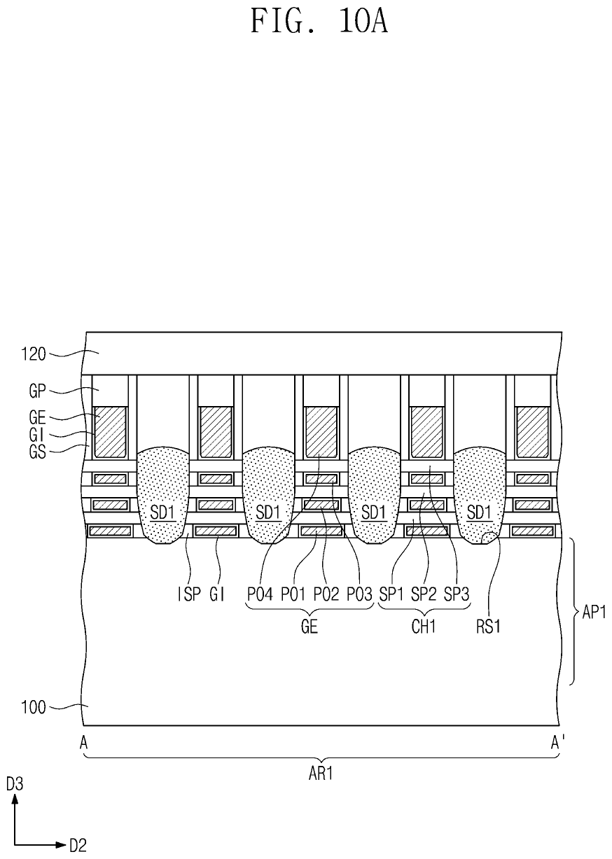

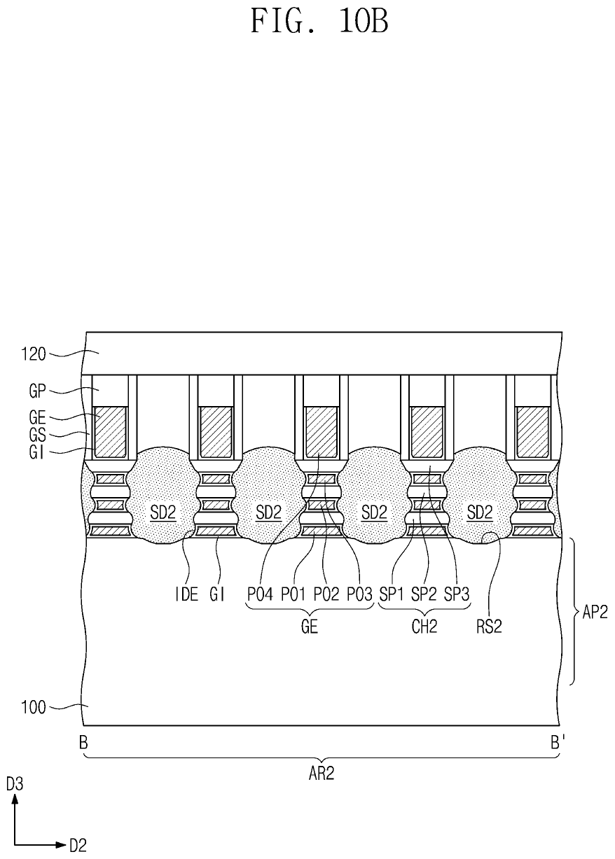

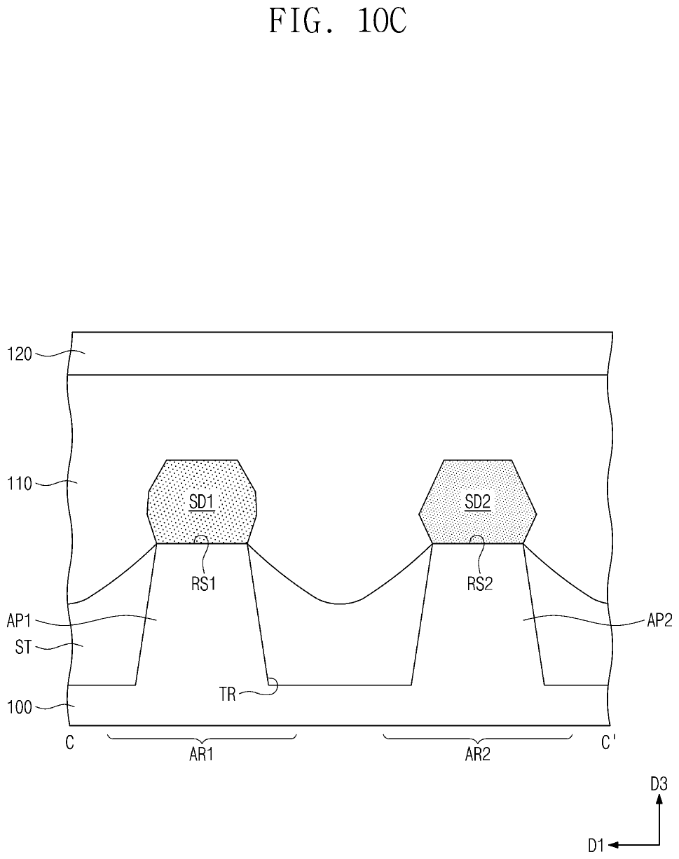

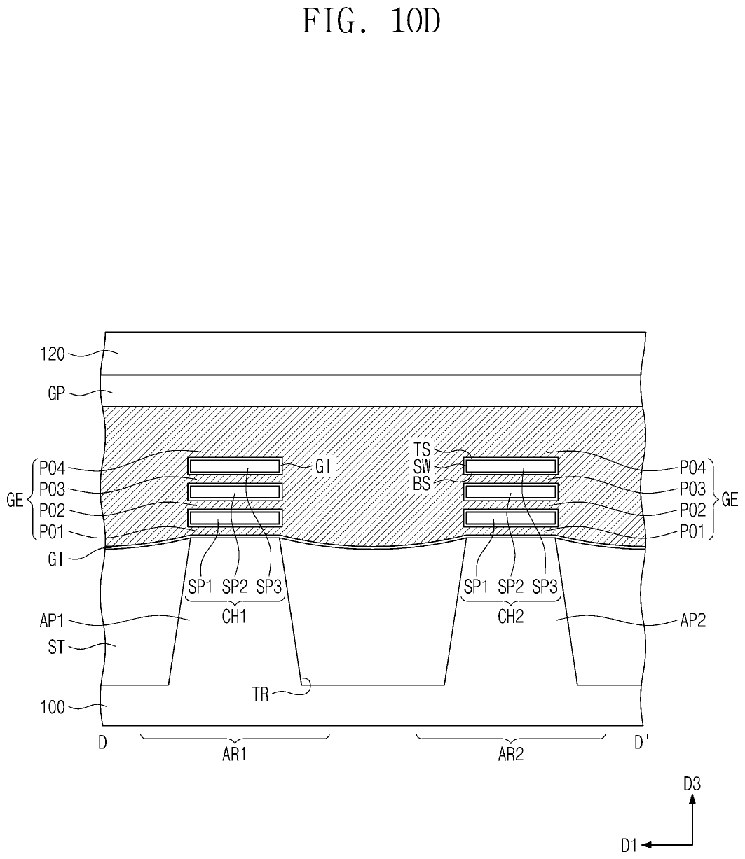

Referring to FIGS. 10A to 10D, a gate electrode GE may be formed on the gate dielectric layer GI. The gate electrode GE may include first, second, and third inner electrodes PO1, PO2, and PO3 that are respectively formed in the first, second, and third inner regions IRG1, IRG2, and IRG3, and may also include an outer electrode PO4 formed in the outer region ORG. The gate electrode GE may be recessed to have a reduced height. A gate capping pattern GP may be formed on the recessed gate electrode GE.

A second interlayer dielectric layer 120 may be formed on the first interlayer dielectric layer 110 and the gate capping pattern GP. The second interlayer dielectric layer 120 may have a constant thickness in a third direction D3. After the formation of the second interlayer dielectric layer 120, a planarization process may be performed.

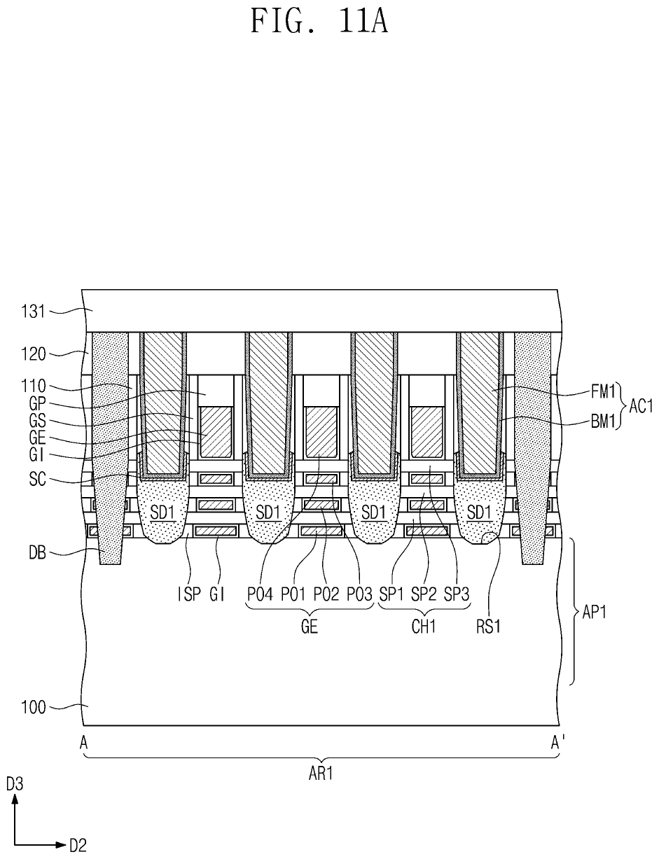

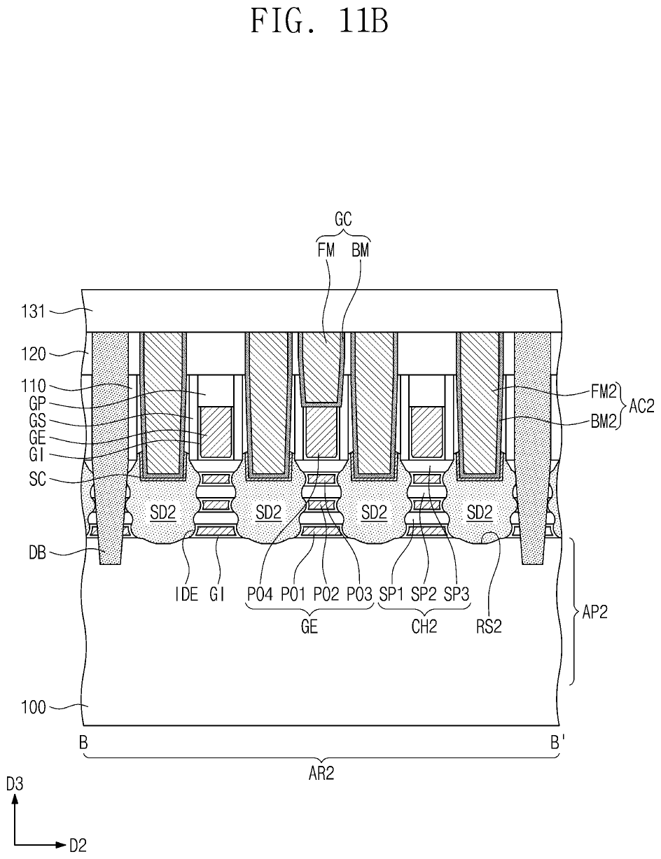

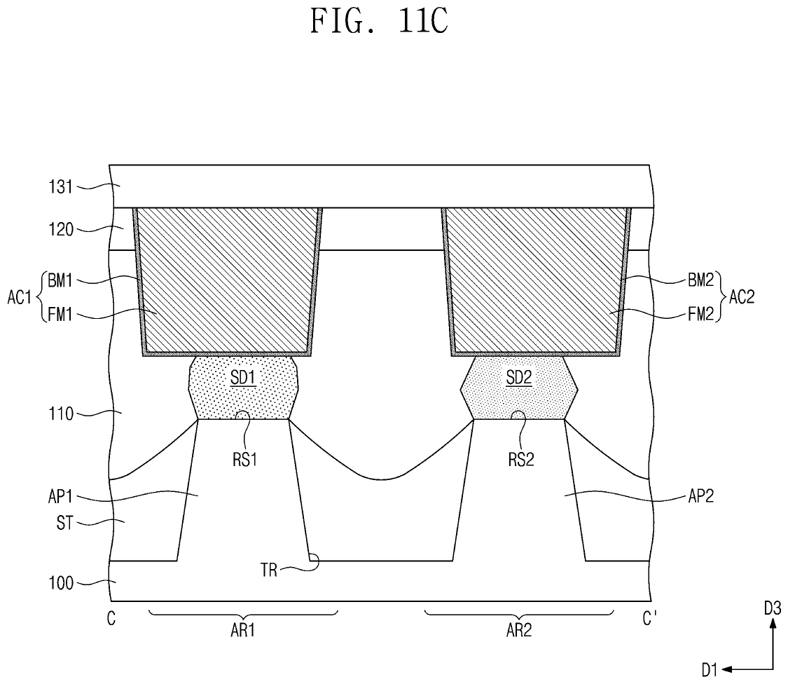

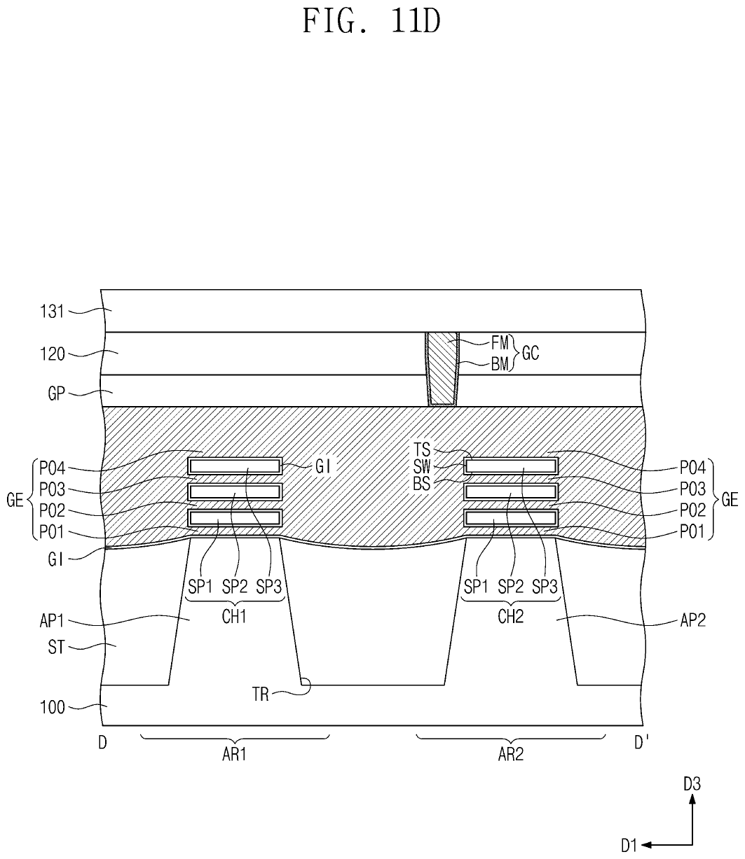

Referring to FIGS. 11A to 11D, a first active contact AC1 and a second active contact AC2 may be formed to penetrate (e.g., at least partially penetrate or extend into) the first interlayer dielectric layer 110 and the second interlayer dielectric layer 120. The first active contact AC1 may be connected (e.g., electrically connected) to an upper portion of the first source/drain pattern SD1. The second active contact AC2 may be connected (e.g., electrically connected) to an upper portion of the second source/drain pattern SD2.

The formation of the first active contact AC1 may include forming a first recess region that penetrates (e.g., at least partially penetrates or extend into) the first and second interlayer dielectric layers 110 and 120, forming a first barrier pattern BM1 in the first recess region, forming a first conductive pattern FM1 on the first barrier pattern BM1, and performing a planarization process on the first conductive pattern FM1.

The formation of the second active contact AC2 may include forming a second recess region that penetrates (e.g., at least partially penetrates or extend into) the first and second interlayer dielectric layers 110 and 120, forming a second barrier pattern BM2 in the second recess region, forming a second conductive pattern FM2 on the second barrier pattern BM2, and performing a planarization process on the second conductive pattern FM2.

The first active contact AC1 and the second active contact AC2 may be formed by the same process or the same series of processes (at the same time). For example, the first and second recess regions may be formed concurrently, the first and second barrier patterns BM1 and BM2 may be formed simultaneously, and the first and second conductive patterns FM1 and FM2 may be formed coincidently. Thereafter, a planarization process may be performed on the first and second conductive patterns FM1 and FM2. In some embodiments, the first active contact AC1 and the second active contact AC2 may be formed independently.

A gate contact GC may be formed to penetrate (e.g., at least partially penetrates) the gate capping pattern GP and the second interlayer dielectric layer 120. The gate contact GC may contact an upper surface of the gate electrode GE (e.g., an upper surface of the outer electrode PO4). The formation of the gate contact GC may include forming a third recess region that penetrates (e.g., at least partially penetrates or extend into) the gate capping pattern GP and the second interlayer dielectric layer 120, forming a barrier pattern BM in the third recess region, forming a conductive pattern FM on the barrier pattern BM, and performing a planarization process on the conductive pattern FM.

A lower interlayer dielectric layer 131 may be formed on the second interlayer dielectric layer 120. The lower interlayer dielectric layer 131 may be disposed on (e.g., cover or overlap) the second interlayer dielectric layer 120, the first active contact AC1, the second active contact AC2, and the gate contact GC.

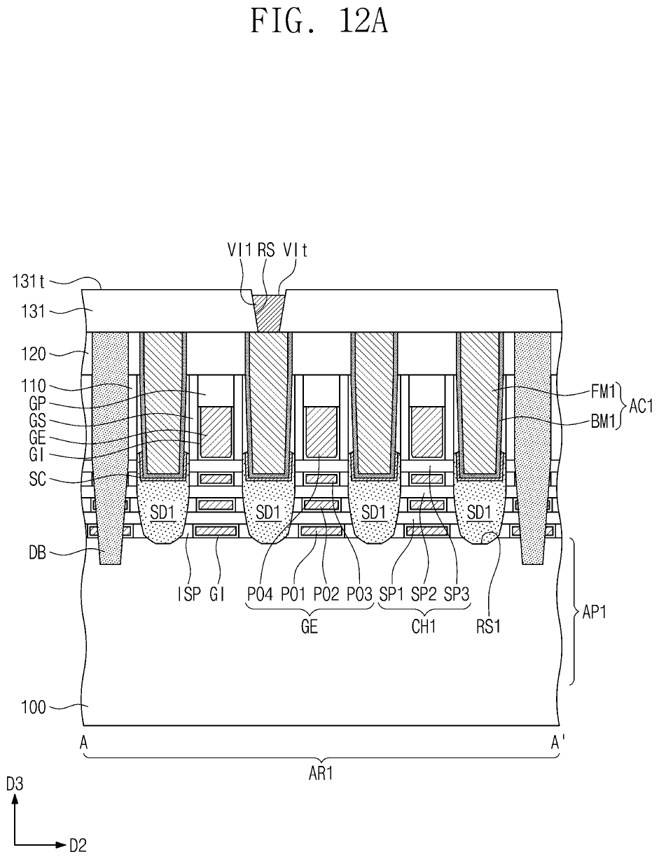

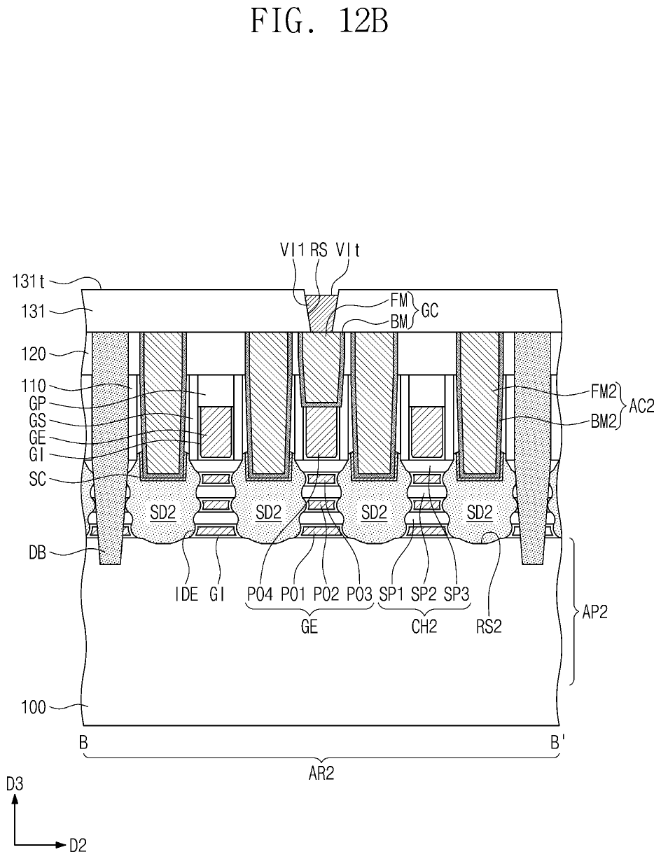

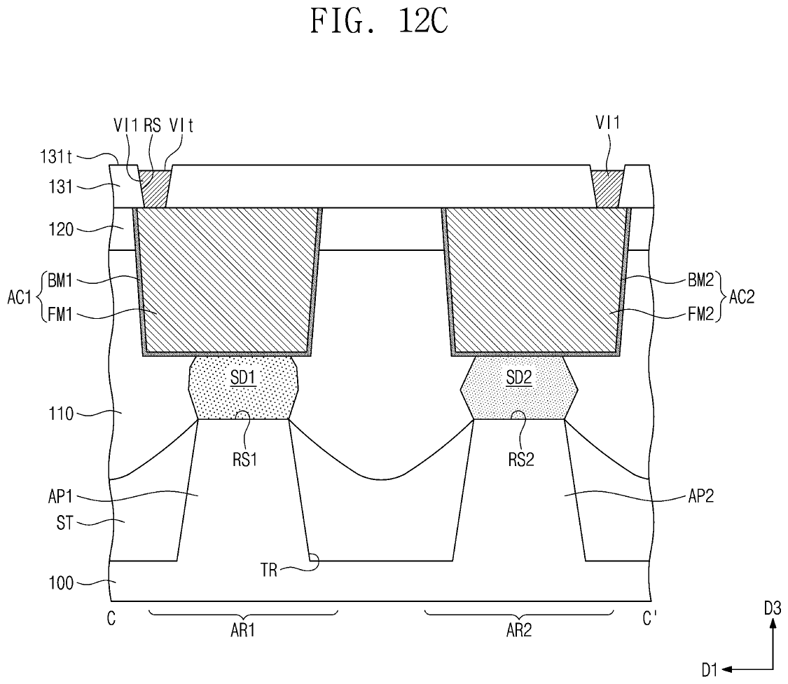

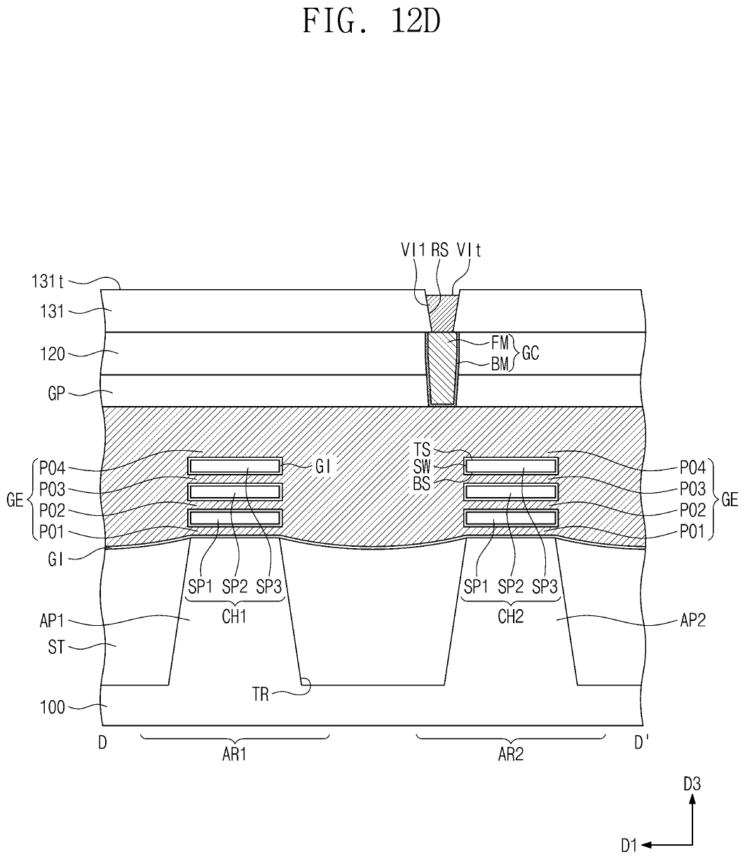

Referring to FIGS. 12A to 12D, the lower interlayer dielectric layer 131 may be patterned to form a recess RS. The formation of the recess RS may include forming a mask on the lower interlayer dielectric layer 131, using the mask to perform an anisotropic etching process on the lower interlayer dielectric layer 131, and removing the mask. The recess RS may penetrate (e.g., at least partially penetrate or extend into) the lower interlayer dielectric layer 131 to outwardly expose at least one of the first active contact AC1, the second active contact AC2, and the gate contact GC. On an upper surface 131t of the lower interlayer dielectric layer 131, a width of the recess RS may decrease with decreasing distance from the second interlayer dielectric layer 120, but the present inventive concepts are not limited thereto. In a cross-sectional view, the recess RS may be in a reversed trapezoid shape.

A first via VI1 may be formed in the recess RS. An upper surface VIt of the first via VI1 may be located at a level lower than that of the upper surface 131t of the lower interlayer dielectric layer 131. The first via VI1 may partially fill the recess RS. The first via VI1 may fill a lower portion of the recess RS.

According to an embodiment, the formation of the first via VI1 may include forming a conductive layer that fills the recess RS and performing a planarization process on the conductive layer. For example, the conductive layer may be on (e.g., cover or overlap) the upper surface 131t of the lower interlayer dielectric layer 131, while filling the recess RS. The planarization process may have a polish selectivity with respect to the lower interlayer dielectric layer 131 and the conductive layer. A portion of the conductive layer may be removed while the lower interlayer dielectric layer 131 is maintained. Thus, the first via VI1 may be formed of the conductive layer to be located at a level lower than that of the upper surface 131t of the lower interlayer dielectric layer 131.

According to an embodiment, the formation of the first via VI1 may include using selective area growth (SAG) to form the first via VI1 in the recess RS. For example, a conductive material may be deposited only on the exposed first active contact AC1, the exposed second active contact AC2, and/or the exposed gate contact GC, thereby selectively forming the first via VI1 only in the recess RS. In this case, because a deposition process can control a height of the first via VI1, the planarization process may be omitted.

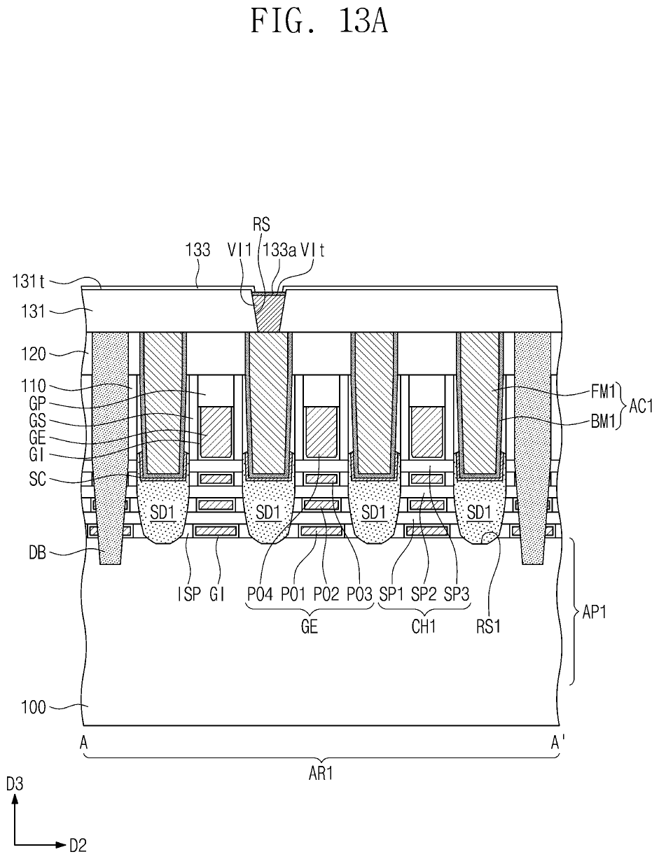

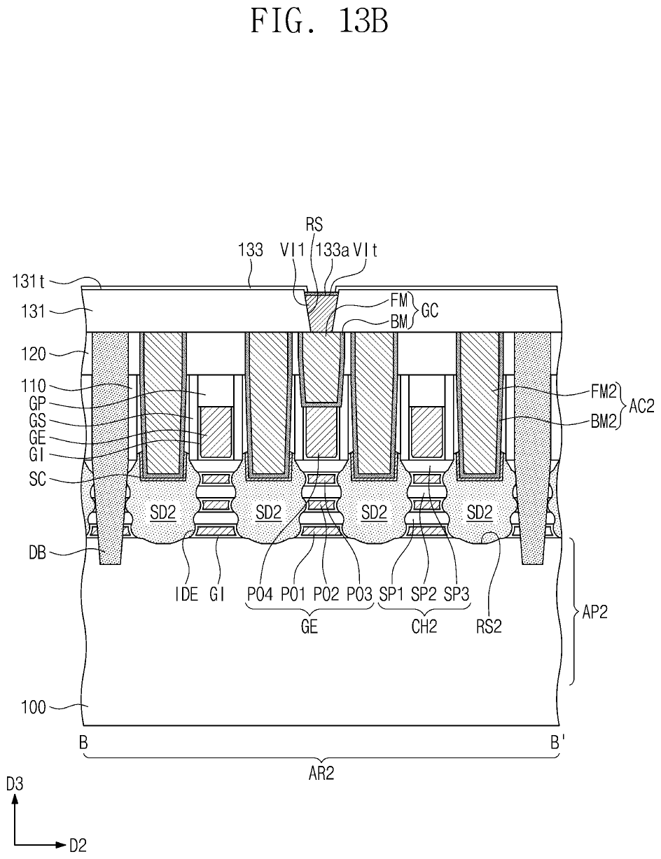

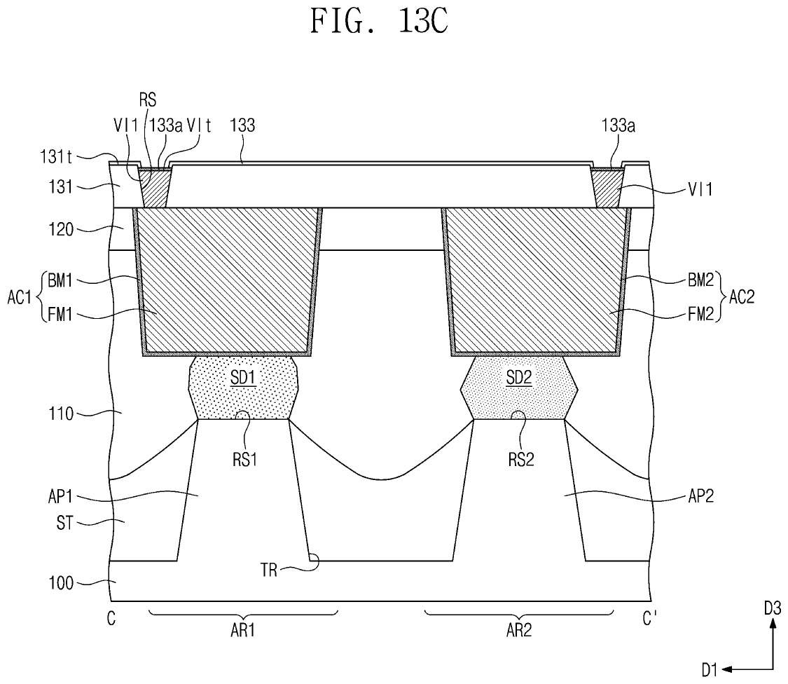

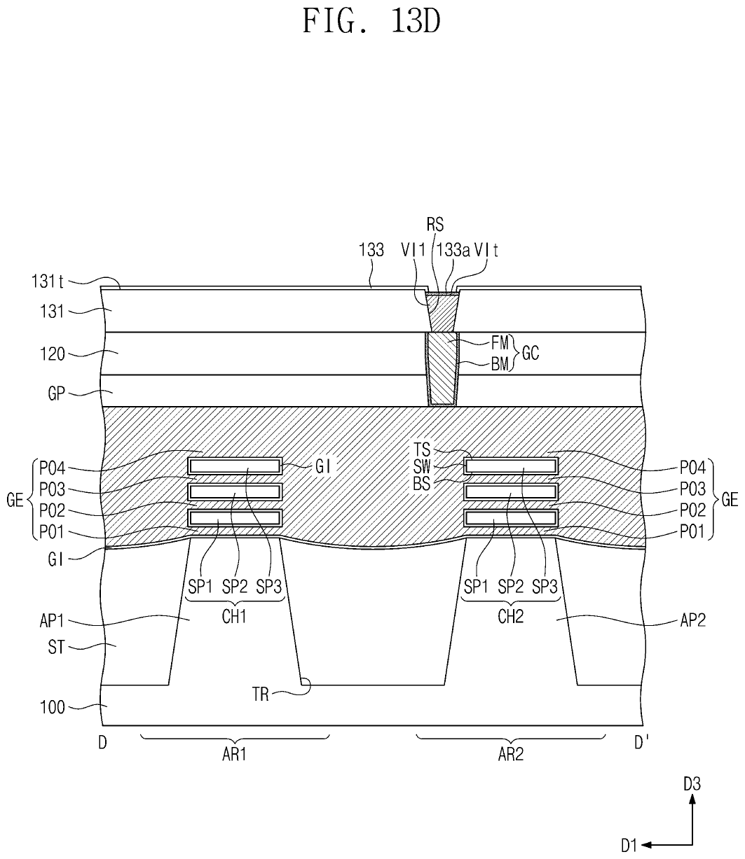

Referring to FIGS. 13A to 13D, a deposition prevention layer 133a may be formed on the upper surface VIt of the first via VI1. The deposition prevention layer 133a may not be formed on the lower interlayer dielectric layer 131. For example, the deposition prevention layer 133a may be selectively formed only on the upper surface VIt of the first via VI1. According to an embodiment, the deposition prevention layer 133a may be a self-assembled monolayer (SAM). For example, the deposition prevention layer 133a may include octadecyl phosphonic acid (ODPA) and/or 1-hexadecanethiol.

An adhesion layer 133 may be formed on the lower interlayer dielectric layer 131. The adhesion layer 133 may have a constant (e.g., uniform) thickness to cover the upper surface 131t of the lower interlayer dielectric layer 131. In addition, as the upper surface VIt of the first via VI1 is located at a level lower than that of the upper surface 131t of the lower interlayer dielectric layer 131, an inner wall of the recess RS may be partially outwardly exposed and thus the adhesion layer 133 may be formed on a portion of the inner wall of the recess RS. For example, the adhesion layer 133 may extend from the upper surface 131t of the lower interlayer dielectric layer 131 to the portion of the inner wall of the recess RS.

The deposition prevention layer 133a may prevent the adhesion layer 133 from being formed on the upper surface VIt of the first via VI1. The adhesion layer 133 may expose at least a portion of the upper surface VIt of the first via VI1. The deposition prevention layer 133a may disturb the formation of the adhesion layer 133 on the upper surface VIt of the first via VI1.

According to an embodiment, the formation of the deposition prevention layer 133a may be omitted. In this case, the adhesion layer 133 may be formed by using selective area growth. For example, the adhesion layer 133 may be formed on the upper surface 131t of the lower interlayer dielectric layer 131 and an outwardly exposed portion of the inner wall of the recess RS.

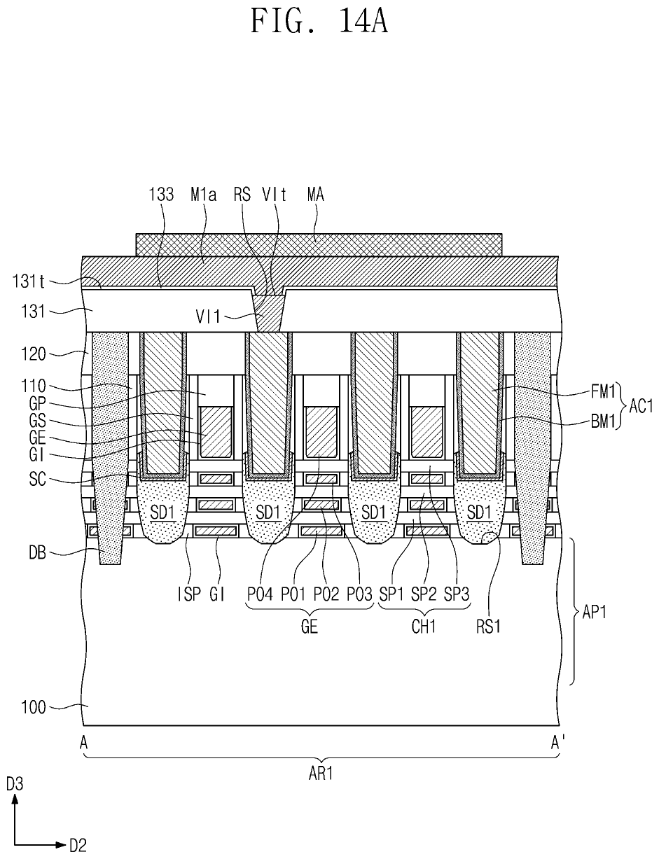

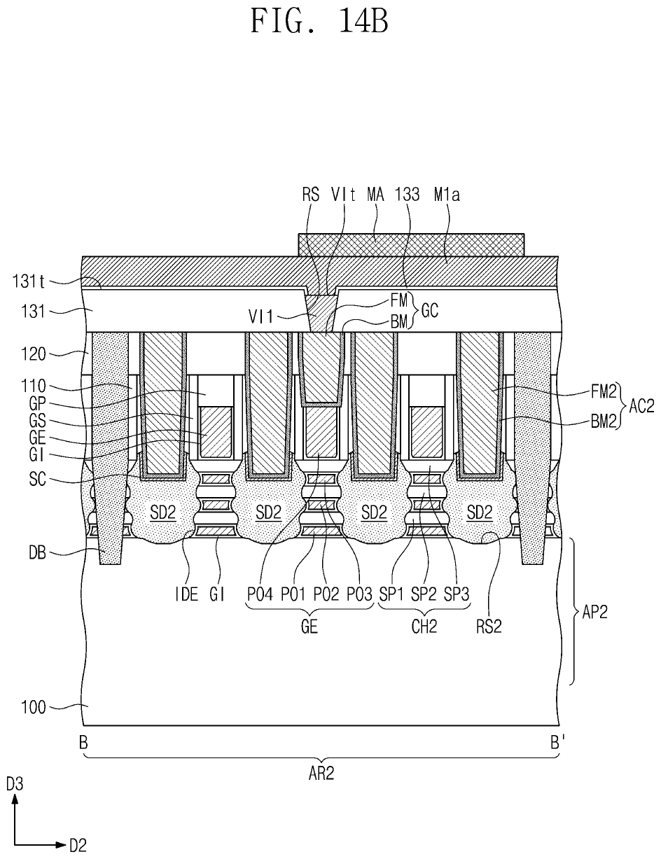

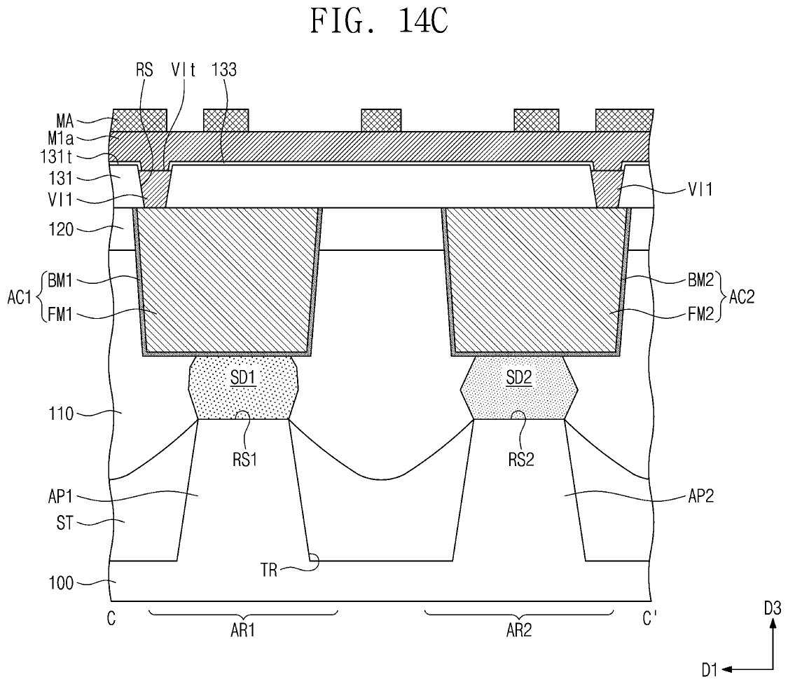

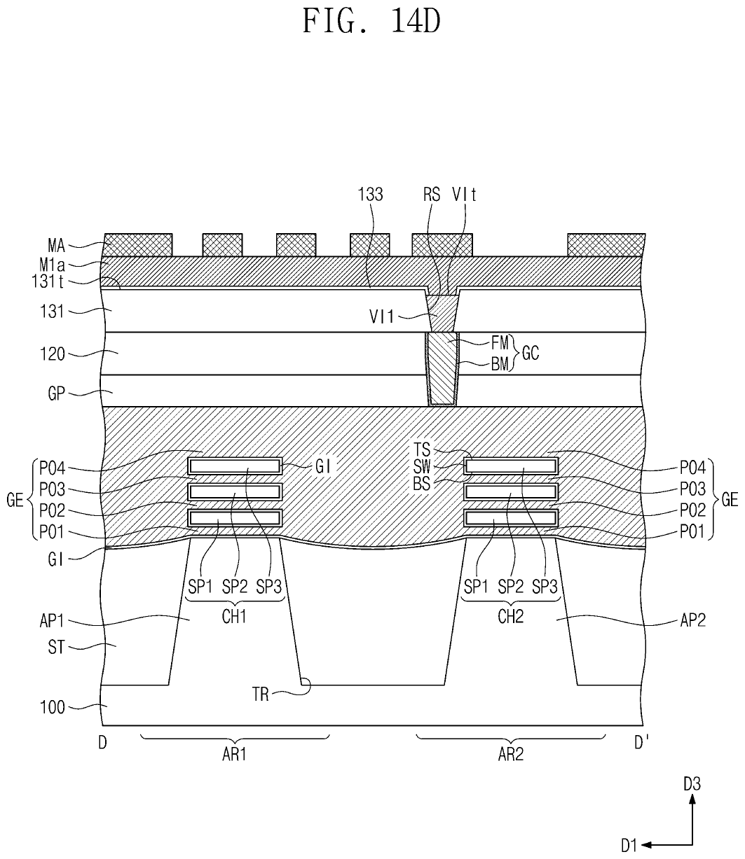

Referring to FIGS. 14A to 14D, a first wiring layer M1a may be formed on the lower interlayer dielectric layer 131, the first via VI1, and the adhesion layer 133. The first wiring layer M1a may be in contact with the adhesion layer 133 and the upper surface VIt of the first via VI1. The formation of the first wiring layer M1a may include removing the deposition prevention layer 133a. For example, the deposition prevention layer 133a may be removed, and then the first wiring layer M1a may be formed.

A deposition process may be used to form the first wiring layer M1a. The deposition process may include, for example, one or a combination of physical vapor deposition (PVD), chemical vapor deposition (CVD), and atomic layer deposition (ALD).

For example, the first wiring layer M1a may include aluminum (Al), copper (Cu), tungsten (W), molybdenum (Mo), ruthenium (Ru), and/or cobalt (Co), and for example, may include ruthenium (Ru).

A mask pattern MA may be formed on the first wiring layer M1a. The formation of the mask pattern MA may include forming a photoresist on the first wiring layer M1a and performing an exposure process on the photoresist.

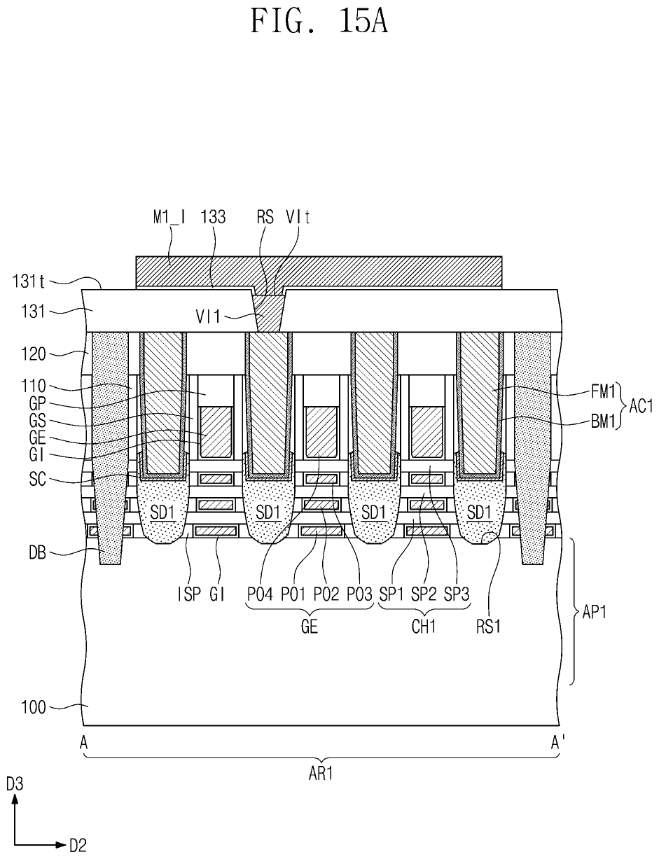

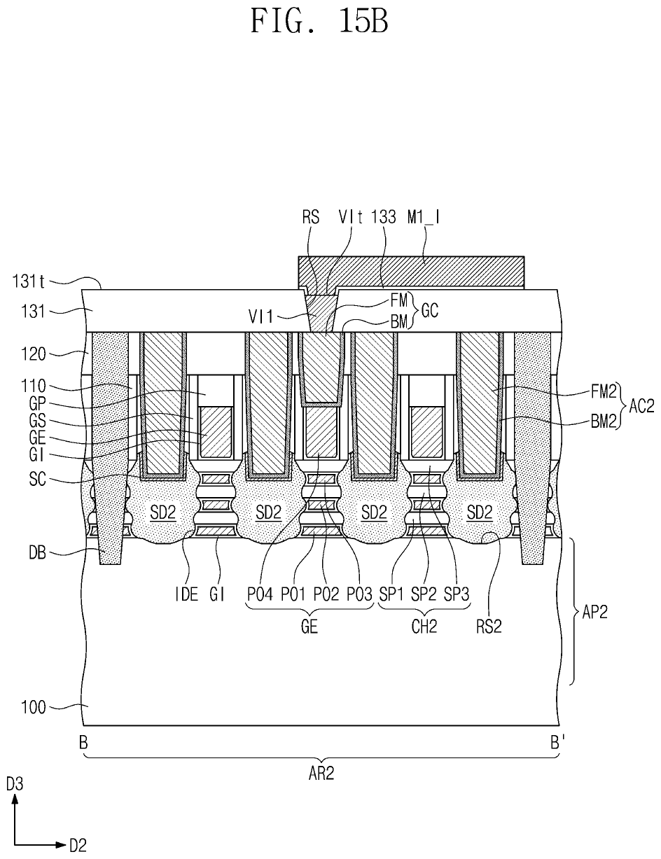

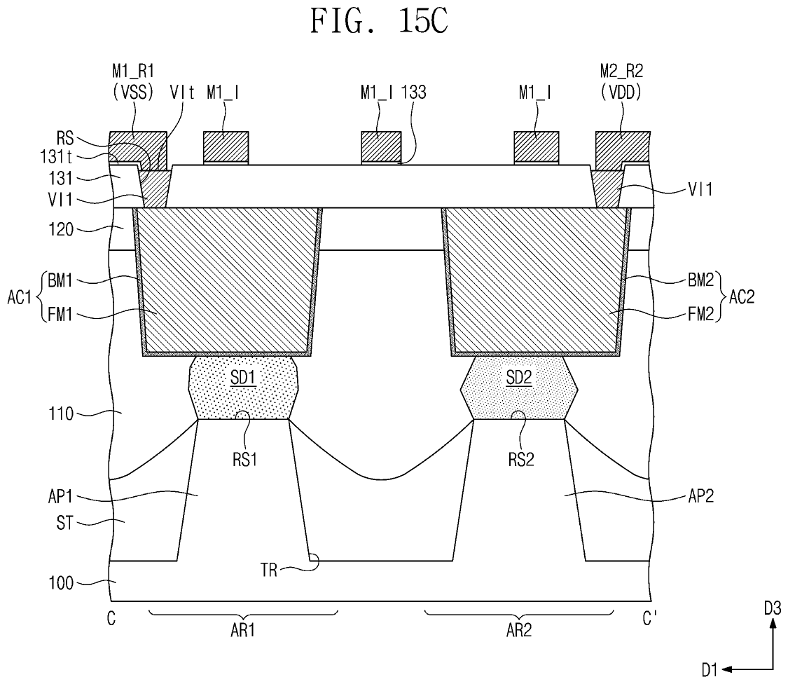

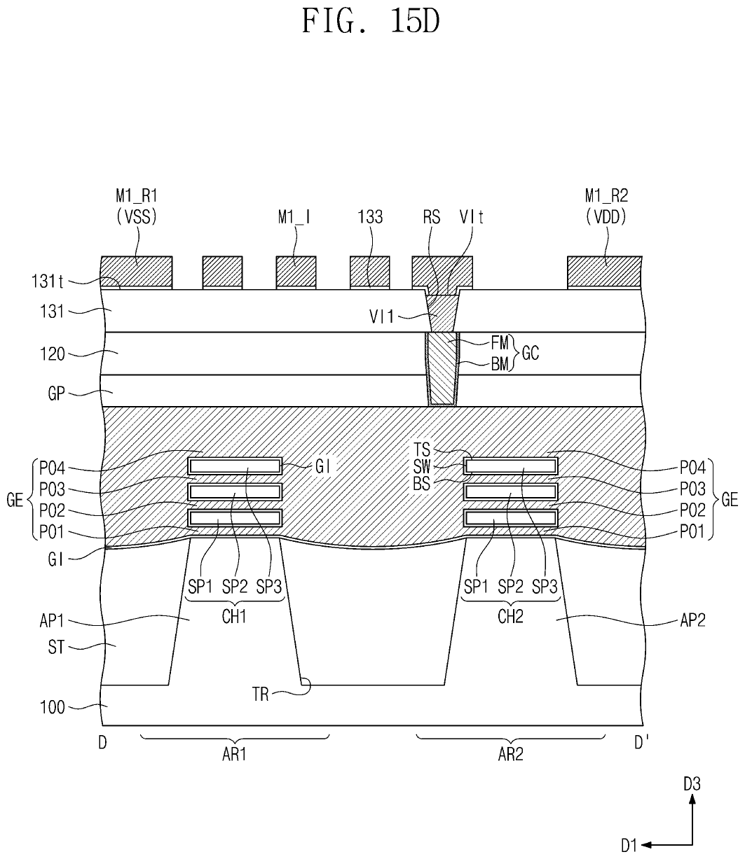

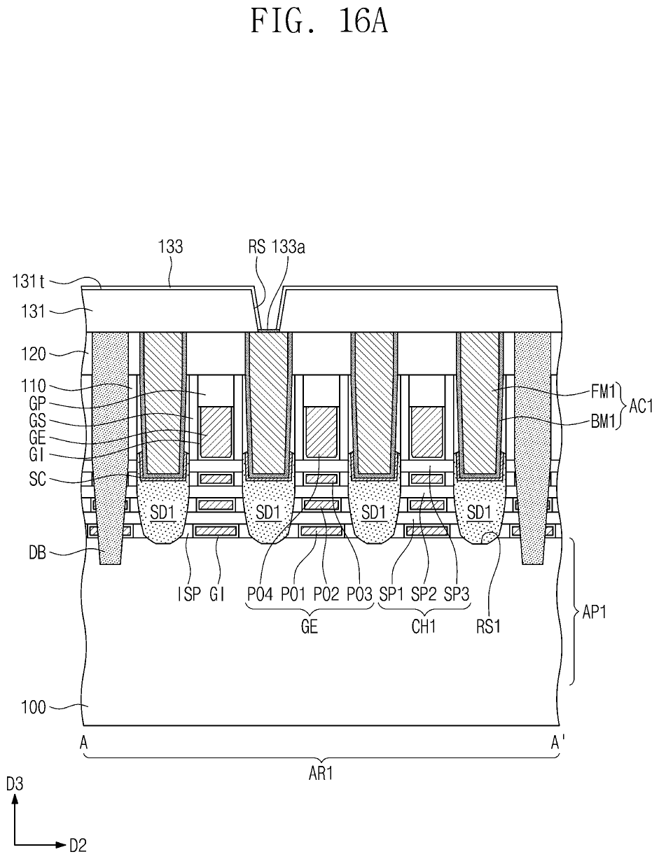

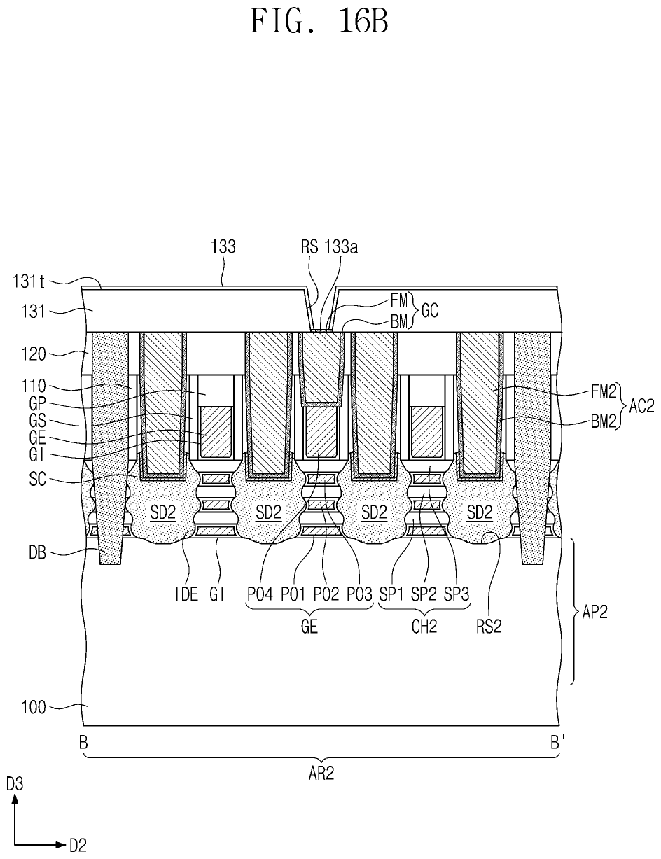

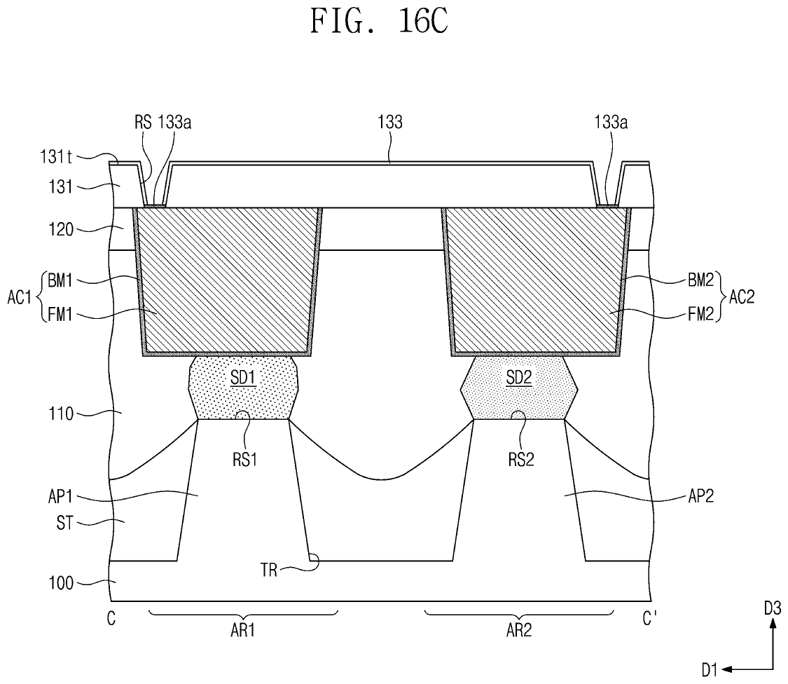

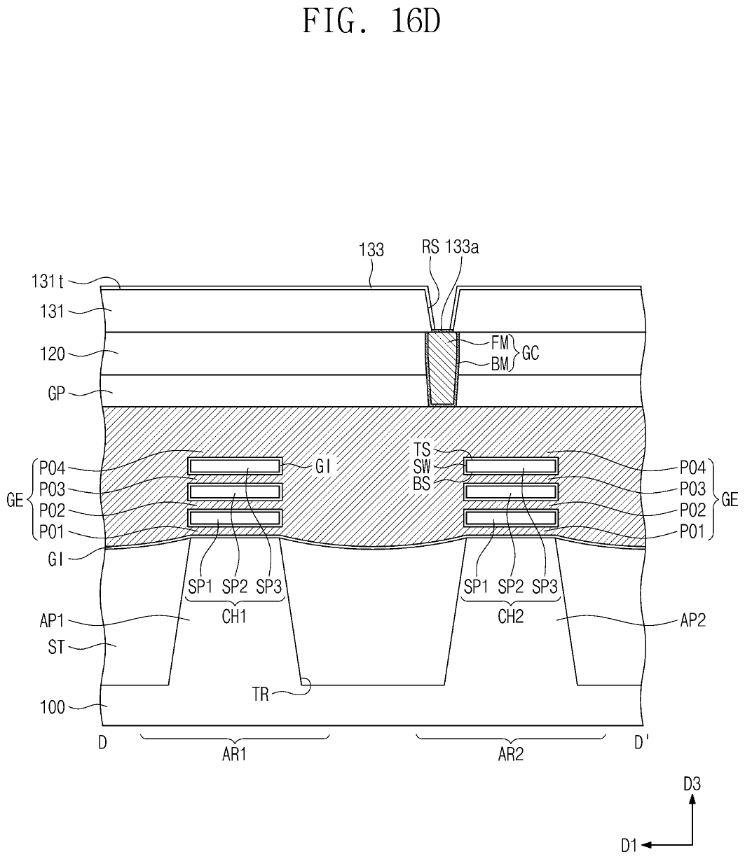

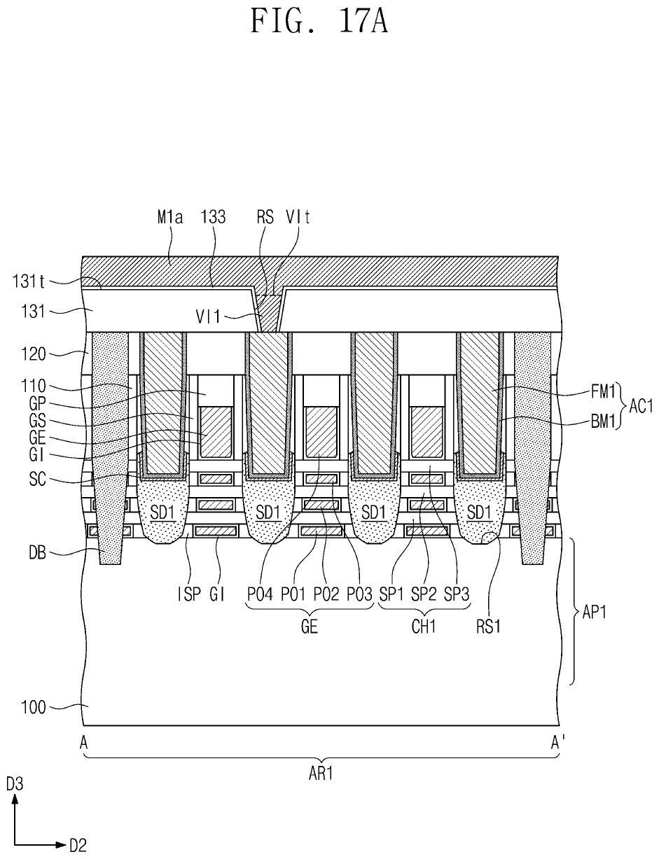

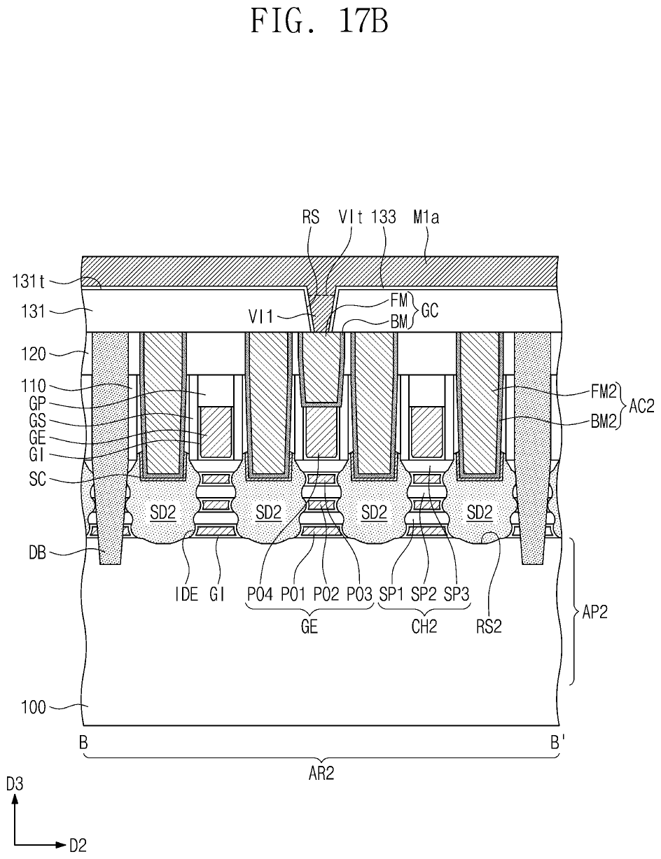

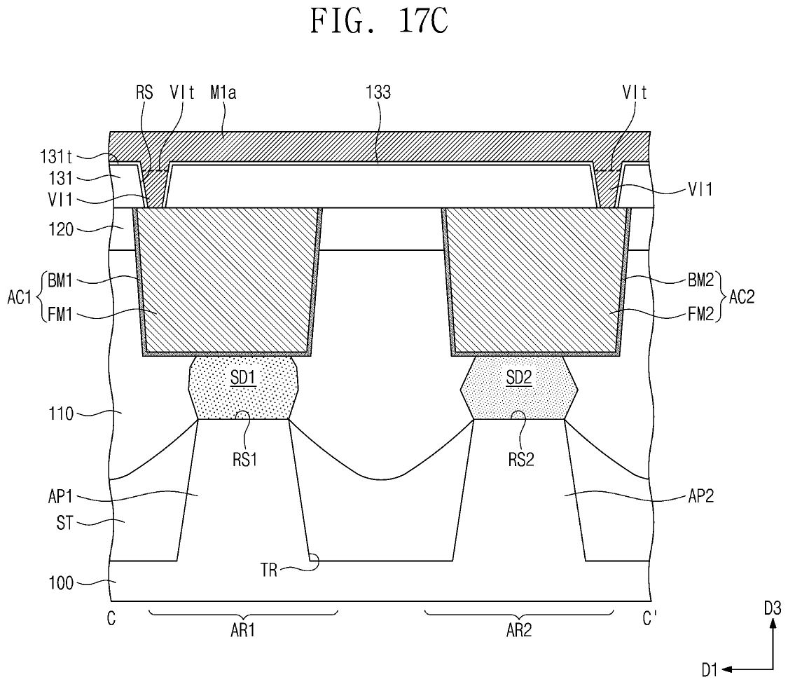

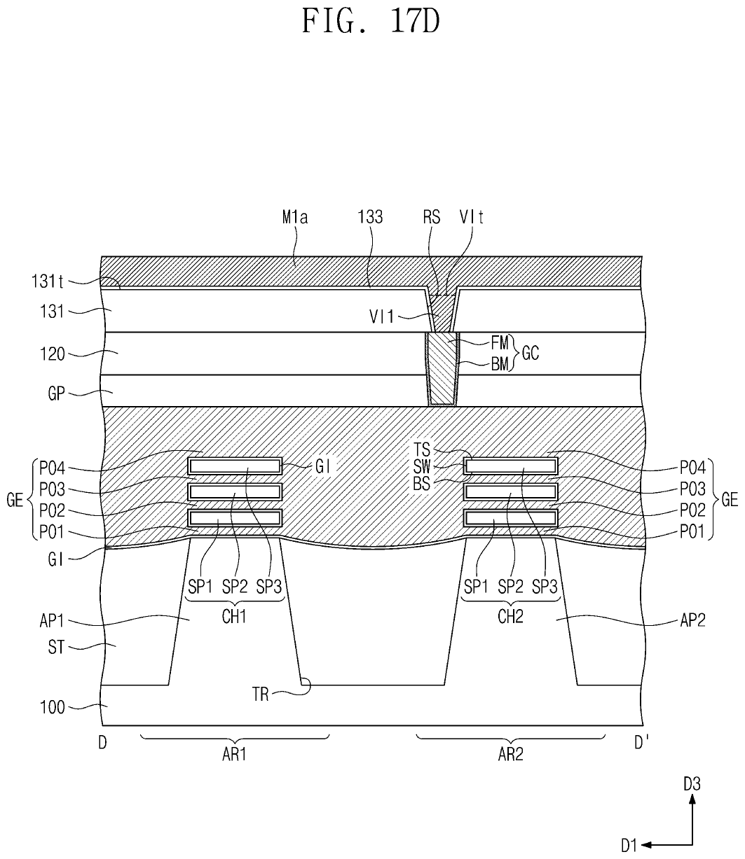

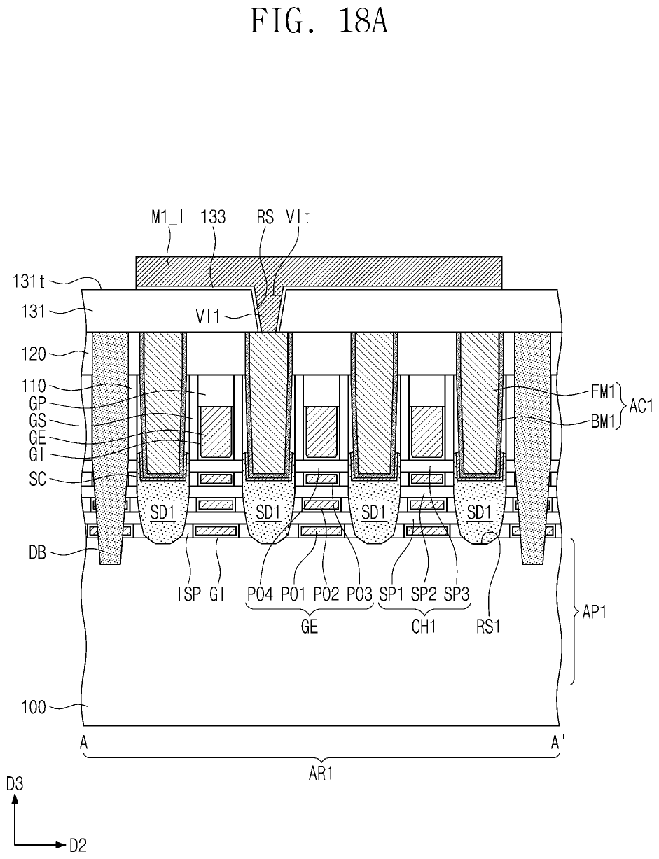

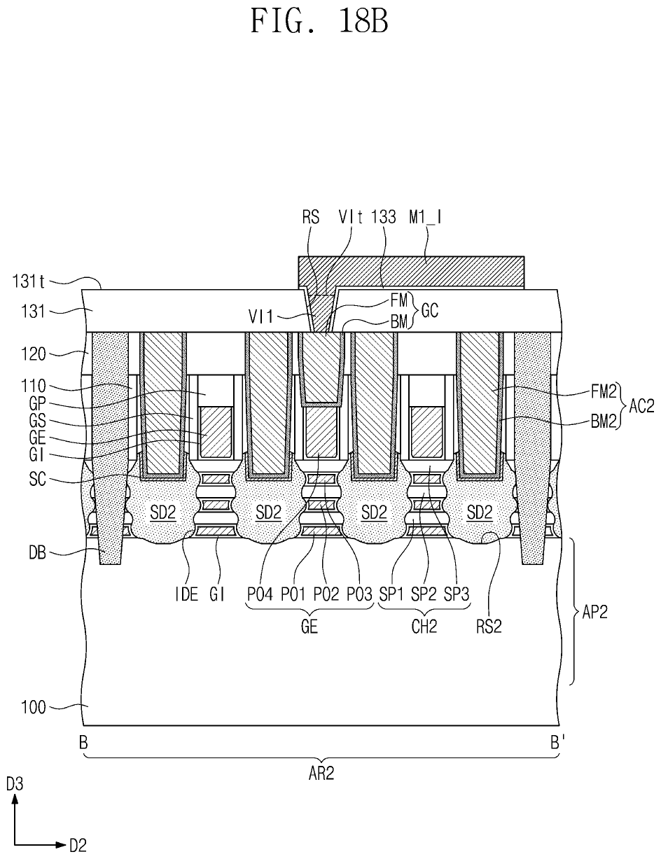

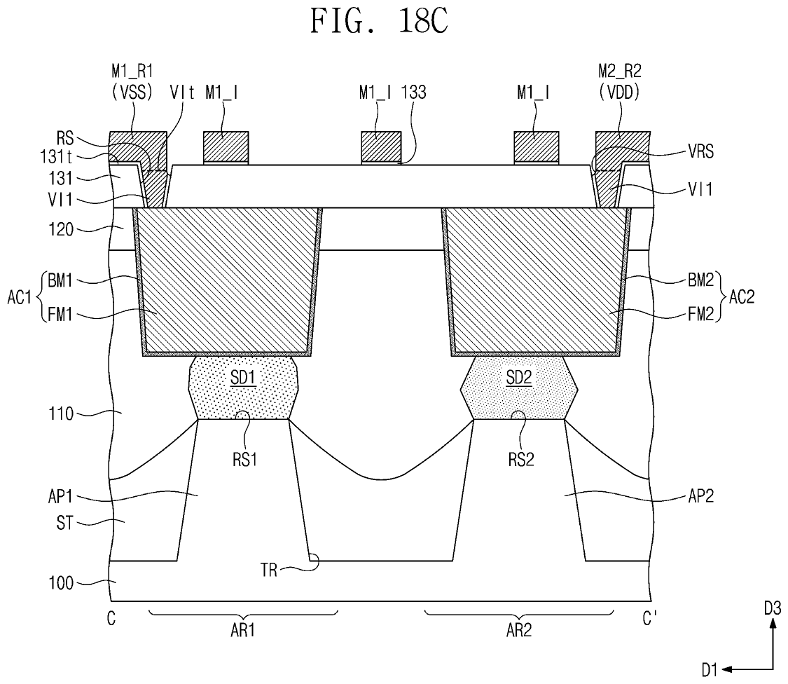

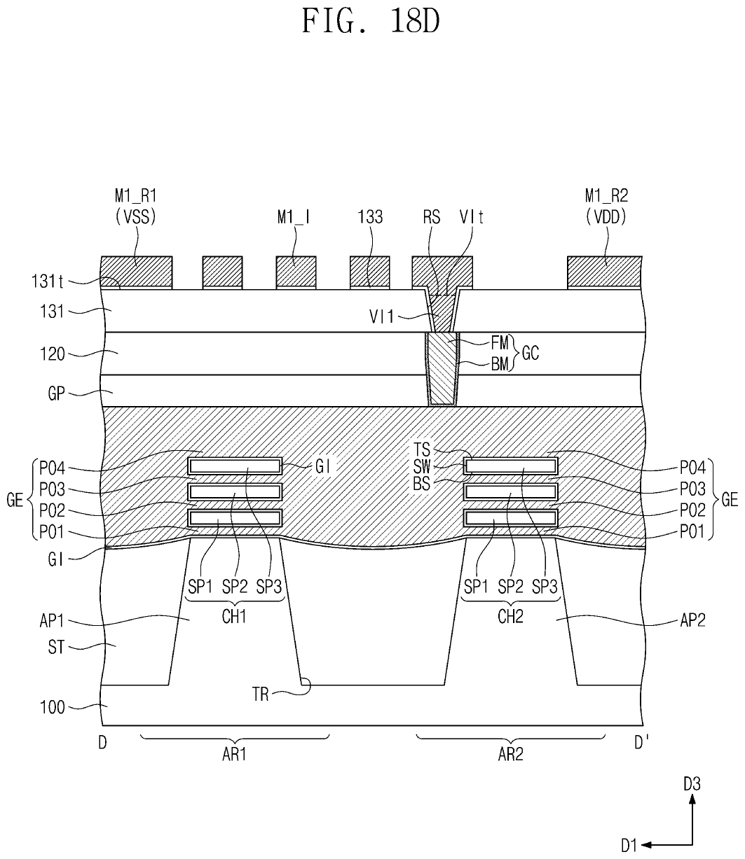

Referring to FIGS. 15A to 15D, the first wiring layer M1a may be patterned to form a first power line M1_R1, a second power line M1_R2, and/or first wiring lines M1_I (of a first metal layer M1) on the lower interlayer dielectric layer 131. For example, the first power line M1_R1, the second power line M1_R2, and the first wiring lines M1_I may be formed from the first wiring layer M1a.

For example, the mask pattern MA may be used as a mask to perform an anisotropic etching process. The anisotropic etching process may remove a portion of the first wiring layer M1a and a portion of the adhesion layer 133. Thus, a portion of the upper surface 131t of the lower interlayer dielectric layer 131 may be outwardly exposed. A portion of the first wiring layer M1a may be removed to form the first power line M1_R1, the second power line M1_R2, and/or the first wiring lines M1_I from the first wiring layer M1a. The first metal layer M1 may thus be formed on the second interlayer dielectric layer 120.

According to an embodiment, the anisotropic etching process may not remove the adhesion layer 133. For example, as shown in FIG. 6B, the adhesion layer 133 may cover the upper surface 131t of the lower interlayer dielectric layer 131. In this case, the adhesion layer 133 may serve as an etch stop layer for the anisotropic etching process.

Referring back to FIGS. 5A to 5D, an upper interlayer dielectric layer 135 may be formed between the first power line M1_R1, the second power line M1_R2, and the first wiring lines M1_I and on the lower interlayer dielectric layer 131.

A fourth interlayer dielectric layer 140 may be formed on the third interlayer dielectric layer 130, and a second metal layer M2 may be formed on the fourth interlayer dielectric layer 140. The formation of the second metal layer M2 may be substantially the same as the formation of the first metal layer M1.

The present inventive concepts, however, are not limited to that discussed above. For example, the second metal layer M2 may be formed by a dual damascene process. A line and its underlying second via VI2 of the second metal layer M2 may be formed by the same process or the same series of processes (e.g., at the same time).

FIGS. 16A to 18D illustrate cross-sectional views showing a method of fabricating a semiconductor device according to some embodiments of the present inventive concepts. FIGS. 16A, 17A, and 18A illustrate cross-sectional views taken along line A-A′ of FIG. 4. FIGS. 16B, 17B, and 18B illustrate cross-sectional views taken along line B-B′ of FIG. 4. FIGS. 16C, 17C, and 18C illustrate cross-sectional views taken along line C-C′ of FIG. 4. FIGS. 16D, 17D, and 18D illustrate cross-sectional views taken along line D-D′ of FIG. 4.

Referring to FIGS. 16A to 16D, a recess RS may be formed by patterning the lower interlayer dielectric layer 131 that covers the second interlayer dielectric layer 120, the first active contact AC1, the second active contact AC2, and/or the gate contact GC. The formation of the second interlayer dielectric layer 120, the first active contact AC1, the second active contact AC2, the gate contact GC may be substantially the same as those discussed in FIGS. 7A to 15D.

The formation of the recess RS may include forming a mask on the lower interlayer dielectric layer 131, using the mask to perform an anisotropic etching process on the lower interlayer dielectric layer 131, and removing the mask. The recess RS may penetrate (e.g., at least partially penetrate or extend into) the lower interlayer dielectric layer 131 to outwardly expose one of the first active contact AC1, the second active contact AC2, and/or the gate contact GC. On an upper surface 131t of the lower interlayer dielectric layer 131, a width of the recess RS may decrease with decreasing distance from the second interlayer dielectric layer 120, but the present inventive concepts are not limited thereto.

A deposition prevention layer 133a may be formed on the exposed first active contact AC1, the exposed second active contact AC2, and/or the exposed gate contact GC. The deposition prevention layer 133a may be formed on upper surfaces of the first active contact AC1, the second active contact AC2, and the gate contact GC, and may not be formed on any of the inner wall (the inner sidewall) of the recess RS and the upper surface 131t of the lower interlayer dielectric layer 131. For example, the deposition prevention layer 133a may be selectively formed only on the upper surfaces of the first active contact AC1, the second active contact AC2, and the gate contact GC. According to an embodiment, the deposition prevention layer 133a may be a self-assembled monolayer (SAM). For example, the deposition prevention layer 133a may include octadecyl phosphonic acid (ODPA) and 1-hexadecanethiol.

An adhesion layer 133 may be formed on the lower interlayer dielectric layer 131. The adhesion layer 133 may have a constant (e.g., uniform) thickness to cover the lower interlayer dielectric layer 131. For example, the adhesion layer 133 may cover the upper surface 131t of the lower interlayer dielectric layer 131 and the inner wall (e.g., inner sidewall) of the recess RS.

The deposition prevention layer 133a may prevent the adhesion layer 133 from being formed on the upper surfaces of the first active contact AC1, the second active contact AC2, and the gate contact GC. In this configuration, the adhesion layer 133 may expose the upper surfaces of the first active contact AC1, the second active contact AC2, and the gate contact GC. The deposition prevention layer 133a may disturb the formation of the adhesion layer 133 on the upper surfaces of the first active contact AC1, the second active contact AC2, and the gate contact GC.

According to an embodiment, the formation of the deposition prevention layer 133a may be omitted. In this case, the adhesion layer 133 may be formed by using selective area growth. The adhesion layer 133 may be formed only on the upper surface 131t of the lower interlayer dielectric layer 131 and the exposed inner wall (e.g., inner sidewall) of the recess RS, and may not be formed on the upper surfaces of the first active contact AC1, the second active contact AC2, and the gate contact GC.

Referring to FIGS. 17A to 17B, after the deposition prevention layer 133a is removed, a first via VI1 and a first wiring layer M1a may be formed on (e.g., to cover or overlap) the adhesion layer 133 and to fill (e.g., at least partially fill) the recess RS. The first via VI1 and the first wiring layer M1a may be formed by one or a combination of physical vapor deposition (PVD), chemical vapor deposition (CVD), and atomic layer deposition (ALD). The first via VI1 may include, for example, ruthenium (Ru) and molybdenum (Mo), and the first wiring layer M1a may include, for example, ruthenium (Ru).

According to an embodiment, selective area growth (SAG) may be used to form the first via VI1 in the recess RS, and then the first wiring layer M1a may be formed on the first via VI and the upper surface 131t of the lower interlayer dielectric layer 131. The first wiring layer M1a may be formed by using, for example, a physical vapor deposition (PVD) process. For example, the first via VI1 and the first wiring layer M1a may be formed by deposition processes different from each other. In this case, a visible interface VIt may be provided between the first via VI1 and the first wiring layer M1a. The interface VIt between the first via VI1 and the first wiring layer M1a may be substantially the same as the upper surface VIt of the first via VI1.

According to one embodiment, the first via VI1 and the first wiring layer M1a may be formed by an in-situ process. For example, the first via VI1 and the first wiring layer M1a may be formed to constitute a single object. In this case, the first via VI1 and the first wiring layer M1a may include the same metallic material. Thus, an invisible interface VIt (or no interface) may be provided between the first via VI1 and the first wiring layer M1a.

Referring to FIGS. 18A to 18D, the first wiring layer M1a may be patterned to form a first power line M1_R1, a second power line M1_R2, and first wiring lines M1_I on the lower interlayer dielectric layer 131. The formation of the first power line M1_R1, the second power line M1_R2, and the first wiring lines M1_I may be substantially the same as that discussed in FIGS. 14A to 15D.

The first wiring lines M1_I may be aligned with the first via VI1 and thus the upper surface VIt of the first via VI1 may not be outwardly exposed, and neither the first power line M1_R1 nor the second power line M1_R2 may be aligned with the first via VI1 and thus a portion of the upper surface VIt of the first via VI1 may be outwardly exposed. Therefore, an exposed portion of the upper surface VIt of the first via VI1 may be removed by the anisotropic etching process for forming the first power line M1_R1, the second power line M1_R2, and the first wiring lines M1_I. Likewise as shown in FIGS. 6A to 6E, the first via VI1 may have a via recess VRS.

A semiconductor device of the present inventive concepts may include a via in an interlayer dielectric layer, a wiring line connected to the via, and an adhesion layer. As the adhesion layer is positioned between the wiring line and the interlayer dielectric layer, the wiring line may be prevented from delamination from the adhesion layer. In addition, as the adhesion layer is excluded between the via and the wiring line, an increase in resistance between the via and the wiring line may be prevented.

As an upper surface of the via is located at a level lower than that of an upper surface of the interlayer dielectric layer, there may a larger distance between the via and other wiring line that is not connected to the via. Therefore, it may be possible to prevent an unintended connection (e.g., an unintended electrical connection) between the via and the wiring line. Accordingly, a semiconductor memory may be obtained which has improved electrical properties and increased reliability.

Although the present invention has been described in connection with the embodiments of the present invention illustrated in the accompanying drawings, it will be understood to those skilled in the art that various changes and modifications may be made without departing from the technical spirit and features of the present invention. It therefore will be understood that the embodiments described above are just illustrative but not limitative in all aspects.

What is claimed is:

1. A semiconductor device, comprising:
a substrate that includes an active pattern;
a channel pattern on the active pattern;
a source/drain pattern electrically connected to the channel pattern;
a gate electrode on the channel pattern;
an interlayer dielectric layer on the gate electrode, wherein the interlayer dielectric layer includes a recess;
a via in the recess of the interlayer dielectric layer;
a wiring line on the interlayer dielectric layer and electrically connected to the via; and
an adhesion layer between the wiring line and an upper surface of the interlayer dielectric layer,
wherein an upper surface of the via is closer than the upper surface of the interlayer dielectric layer to the substrate in a first direction,
wherein the first direction is perpendicular to an upper surface of the substrate and
wherein a portion of the adhesion layer is on a portion of an inner sidewall of the recess.

2. The semiconductor device of claim 1, wherein the wiring line includes a line portion and a protrusion portion that extends from the line portion in the first direction,
wherein the line portion is on the upper surface of the interlayer dielectric layer, and
wherein at least a portion of the protrusion portion is in the recess of the interlayer dielectric layer.

3. The semiconductor device of claim 2, wherein the protrusion portion of the wiring line is in contact with the upper surface of the via.

4. The semiconductor device of claim 1, wherein the upper surface of the via has a shape that is convex toward the wiring line.

5. The semiconductor device of claim 1, wherein at least a portion of the upper surface of the via is exposed through the adhesion layer to be in contact with the wiring line.

6. The semiconductor device of claim 1, wherein the adhesion layer has a sidewall aligned with one sidewall of the wiring line.

7. The semiconductor device of claim 1, wherein the via is electrically connected to the source/drain pattern or the gate electrode.

8. The semiconductor device of claim 1, wherein the wiring line includes ruthenium (Ru).

9. The semiconductor device of claim 1, further comprising a contact between the source/drain pattern and the via or between the gate electrode and the via,
wherein the contact includes:
a conductive pattern; and
a barrier pattern on sidewalls and a lower surface of the conductive pattern.

10. The semiconductor device of claim 1, wherein the channel pattern includes a plurality of semiconductor patterns that are spaced apart from each other and are stacked in the first direction,
wherein the gate electrode includes:
a plurality of inner electrodes between adjacent ones of the plurality of semiconductor patterns; and
an outer electrode on an uppermost one of the plurality of semiconductor patterns.

11. A semiconductor device, comprising:
a substrate that includes an active pattern;
a device isolation layer adjacent to the active pattern;
a channel pattern on the active pattern, wherein the channel pattern includes a plurality of semiconductor patterns that are stacked and spaced apart from each other in a first direction, and wherein the first direction is perpendicular to an upper surface of the substrate;
a source/drain pattern electrically connected to the plurality of semiconductor patterns;
a gate electrode that extends around the plurality of semiconductor patterns;
an active contact electrically connected to the source/drain pattern;
a gate contact electrically connected to the gate electrode;
an interlayer dielectric layer on the active contact and the gate contact, wherein the interlayer dielectric layer includes a recess;
a via in the recess of the interlayer dielectric layer and electrically connected to the active contact or the gate contact;
a plurality of wiring lines on the interlayer dielectric layer; and
an adhesion layer between the interlayer dielectric layer and the plurality of wiring lines,
wherein one of the plurality of wiring lines is electrically connected to the via, and
wherein the adhesion layer extends from an upper surface of the interlayer dielectric layer to a portion of an inner sidewall of the recess.

12. The semiconductor device of claim 11, wherein an upper surface of the via is lower than the upper surface of the interlayer dielectric layer with respect to the upper surface of the substrate in the first direction.

13. The semiconductor device of claim 11, wherein each of the plurality of wiring lines includes a line portion and a protrusion portion that extends from the line portion in the first direction,
wherein the line portion is spaced apart from an upper surface of the via in the first direction.

14. The semiconductor device of claim 13, wherein the via and one of the plurality of wiring lines are integrally connected to each other.

15. A method of fabricating a semiconductor device, the method comprising:
forming an interlayer dielectric layer on a substrate;
patterning the interlayer dielectric layer to form a recess;
forming a via in the recess;
forming an adhesion layer that is on a portion of an inner sidewall of the recess and an upper surface of the interlayer dielectric layer, wherein the adhesion layer exposes an upper surface of the via;
forming a wiring layer on the adhesion layer and the upper surface of the via; and
patterning the wiring layer to form a plurality of wiring lines,
wherein the upper surface of the via is lower than the upper surface of the interlayer dielectric layer with respect to an upper surface of the substrate in a first direction, and
wherein the first direction is perpendicular to the upper surface of the substrate.

16. The method of claim 15, before forming the adhesion layer, the method further comprising forming a deposition prevention layer on the via.

17. The method of claim 16, wherein the deposition prevention layer includes octadecyl phosphonic acid (ODPA) and/or 1-hexadecanethiol.

18. The method of claim 15, wherein forming the via includes:
forming a conductive layer that is in the recess; and
performing a planarization process on the conductive layer.

19. The method of claim 15, wherein forming the via includes using selective area growth.

20. The method of claim 15, wherein forming the plurality of wiring lines includes patterning the adhesion layer.
